(19) United States
(12) Patent Application Publication
(10) Pub. No.: US 2023/0261502 A1
(43) Pub. Date: Aug. 17, 2023

(54) METHOD AND ELECTRONIC DEVICE FOR CONTROLLING DISCHARGE OF BATTERY

(71) Applicant: SAMSUNG ELECTRONICS CO., LTD., Suwon-si (KR)

(72) Inventors: Jongmin YOON, Suwon-si (KR); Bokun CHOI, Suwon-si (KR); Seungnyun KIM, Suwon-si (KR)

(21) Appl. No.: 18/306,485

(22) Filed: Apr. 25, 2023

Related U.S. Application Data
(63) Continuation of application No. PCT/KR2022/015346, filed on Oct. 12, 2022.

(30) Foreign Application Priority Data
Nov. 11, 2021 (KR) 10-2021-0155054

(51) Int. Cl. H02J 7/00

(52) U.S. Cl. CPC H02J 7/007194; H02J 7/0013; G06F 1/3206

(57) ABSTRACT

An electronic device may include a first battery, a second battery connected in parallel with the first battery, a first current control module configured to control a first discharge current of the first battery, a second current control module configured to control a second discharge current of the second battery, a sensor module configured to sense a temperature of the first battery and a temperature of the second battery, a memory, and a processor operatively connected to the first current control module, the second current control module, the sensor module, and the memory. The processor may measure the temperature of the first battery and the temperature of the second battery by using the sensor module, identify whether at least one reference condition is satisfied, based on the temperature of the first battery and the temperature of the second battery, control the first discharge current of the first battery by using the first current control module when the at least one reference condition is satisfied, and control the second discharge current of the second battery by using the second current control module. Various other embodiments may be possible.

### CROSS-REFERENCE TO RELATED APPLICATIONS

This application is a continuation of International Application No. PCT/KR2022/015346, designating the United States, filed on Oct. 12, 2022, in the Korean Intellectual Property Receiving Office, and claiming priority to KR Patent Application No. 10-2021-0155054 filed on Nov. 11, 2021, in the Korean Intellectual Property Office, the disclosures of all of which are hereby incorporated by reference herein in their entireties.

### BACKGROUND

### Field

Various embodiments relate to a method and/or an electronic device for controlling discharge of a battery.

### Description of Related Art

With the development of digital technology, various types of electronic devices, such as mobile communication terminals, personal digital assistants (PDAs), electronic organizers, smartphones, tablet personal computers (PCs), and wearable devices are widely used. In order to support and increase functions of such electronic devices, hardware parts and/or software parts of the electronic devices have been continuously improved.

For example, an electronic device may provide virtual reality (VR) which enables a user to experience the same as real life in a virtual world created by a computer. In addition, the electronic device may provide augmented reality (AR) in which virtual information (or object) is added to the real world and displayed, and mixed reality (MR) in which virtual reality and augmented reality are mixed. The electronic device may include an augmented reality (AR) electronic device (e.g., a head-up display) for providing virtual reality and augmented reality.

An AR electronic device may be worn on a user's head part and may include a display module for providing virtual reality to a user. The AR electronic device may be at least partially mounted on ears of the user so that the display module is disposed to correspond to the user's eye position. For example, the AR electronic device may include a first support portion mounted on a left ear and a second support portion mounted on a right ear. The first support portion and the second support portion may provide a space in which at least one component is disposed, and individually include a first battery and a second battery.

### SUMMARY

In general, an electronic device may recognize a first battery and a second battery as an integrated single battery, and operate at least one component, based on a current discharged from the integrated battery. For example, the electronic device may be driven using a current equally discharged from the first battery and the second battery and, when a total amount of discharged current is reduced, the electronic device may operate in such a manner of exhibiting at least partially limited functions to reduce current consumption.

An example embodiment is to provide an electronic device capable of independently controlling a first discharge current of a first battery and a second discharge current of a second battery.

According to various example embodiments, an electronic device may include a first battery, a second battery connected, directly or indirectly, in parallel with the first battery, a first current control module (comprising circuitry) configured to control a first discharge current of the first battery, a second current control module (comprising circuitry) configured to control a second discharge current of the second battery, a sensor module configured to sense a temperature of the first battery and a temperature of the second battery, a memory, and a processor operatively connected, directly or indirectly, to the first current control module, the second current control module, the sensor module, and the memory. The processor may measure the temperature of the first battery and the temperature of the second battery by using the sensor module, identify whether at least one reference condition is satisfied, based on the temperature of the first battery and the temperature of the second battery, control the first discharge current of the first battery by using the first current control module when the at least one reference condition is satisfied, and control the second discharge current of the second battery by using the second current control module.

A method according to various example embodiments may include measuring a temperature of a first battery and a temperature of a second battery by using a sensor module, identifying whether at least one reference condition is satisfied, based on the measured temperature of the first battery and the measured temperature of the second battery, controlling a first discharge current of the first battery by using a first current control module when the at least one reference condition is satisfied, and controlling a second discharge current of the second battery by using a second current control module when the at least one reference condition is satisfied.

In various example embodiments, an electronic device including a first battery and a second battery may independently control an amount of current discharged from the batteries by using a first current control module corresponding to the first battery and a second current control module corresponding to the second battery. For example, when the temperature of a battery rises due to a problem occurring therein, an amount of current discharged from the battery having the risen temperature may be reduced, and an amount of current discharged from the battery of which the temperature has not risen may be increased so as to adjust a total amount of current supplied to a system.

According to an example embodiment, an electronic device may individually adjust an amount of current (e.g., a first discharge current and/or a second discharge current) discharged from each battery in a state in which a plurality of batteries (e.g., a first battery and/or a second battery) are disposed, and at least partially control the operation of the electronic device (e.g., a system), based on a total amount of current. According to an embodiment, even when an abnormal situation (e.g., rapid rise in temperature) with respect to the batteries occurs, the use stability of the electronic device may be maintained and the usability of the electronic device may be improved. In addition, various effects identified directly or indirectly through this document may be provided.

### BRIEF DESCRIPTION OF DRAWINGS

In relation to the description of drawings, the same or similar reference numerals may be used for the same or similar components. Example aspects, advantages, and prominent features of the disclosure will become clear to those skilled in the art from the following detailed description that discloses various example embodiments together with the accompanying drawings, in which:

FIG. 1 is a block diagram of an electronic device in a network environment according to various example embodiments;

FIG. 2 is an overall configuration diagram of an electronic device including a plurality of batteries and a plurality of current control modules for the respective batteries according to various example embodiments;

FIG. 3 is a block diagram of an electronic device including a plurality of current control modules for managing a plurality of batteries according to various example embodiments;

FIG. 4 is a flowchart illustrating a method for controlling an amount of current discharged from a plurality of batteries according to various example embodiments;

FIG. 5 is a flowchart illustrating a method for measuring temperatures of a plurality of batteries and controlling an amount of current discharged from the plurality of batteries, based on the measured temperatures, according to various example embodiments;

FIG. 6 is a configuration diagram of an electronic device in which a plurality of batteries and a temperature sensor for measuring a temperature of each of the batteries are disposed, according to various example embodiments;

FIG. 7A is a first graph illustrating a situation in which a first discharge current of a first battery is reduced while a second discharge current of a second battery is maintained at a supportable level, according to various example embodiments;

FIG. 7B is a second graph illustrating a total amount of current supplied to an electronic device in a situation in which a first discharge current of a first battery is reduced while a second discharge current of a second battery is maintained at a supportable level, according to various example embodiments;

FIG. 8A is a third graph illustrating a situation in which a first discharge current of a first battery and a second discharge current of a second battery are reduced, according to various example embodiments; and

FIG. 8B is a fourth graph illustrating a total amount of current supplied to an electronic device in a situation in which a first discharge current of a first battery and a second discharge current of a second battery are reduced, according to various example embodiments.

### DETAILED DESCRIPTION

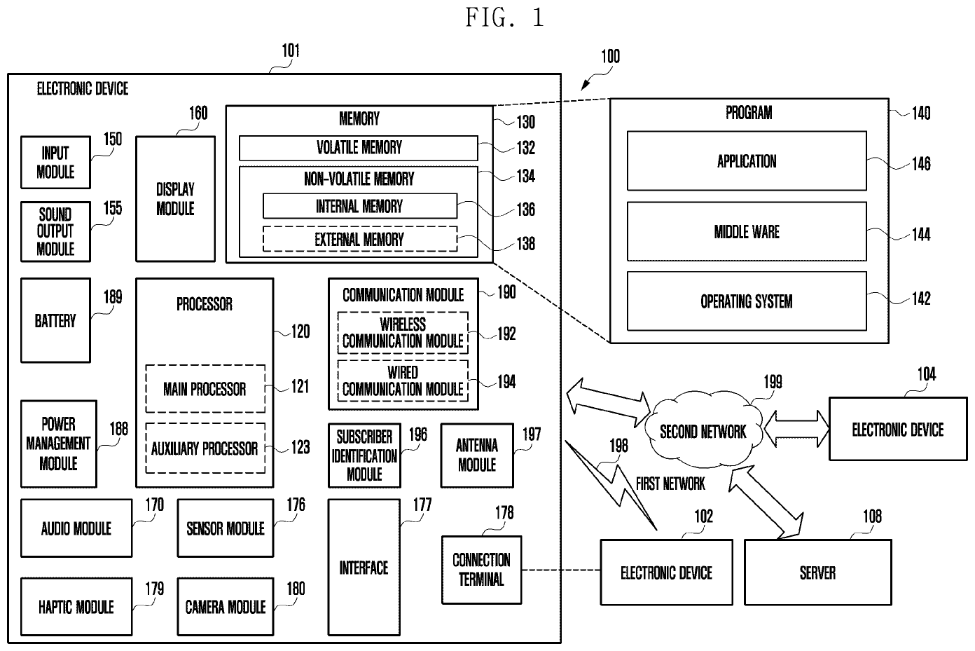

FIG. 1 illustrates an electronic device in a network environment according to an embodiment of the disclosure. Referring to FIG. 1, an electronic device 101 in a network environment 100 may communicate with an electronic device 102 via a first network 198 (e.g., a short-range wireless communication network), or at least one of electronic device 104 or a server 108 via a second network 199 (e.g., a long-range wireless communication network). The electronic device 101 may communicate with the electronic device 104 via the server 108. The electronic device 101 includes a processor 120, memory 130, an input module 150, an audio output module 155, a display module 160, an audio module 170, a sensor module 176, an interface 177, a connecting terminal 178, a haptic module 179, a camera module 180, a power management module 188, a battery 189, a communication module 190, a subscriber identity module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. As at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. The processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). The auxiliary processor 123 (e.g., an ISP or a CP) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134. The non-volatile memory 134 may include an internal memory 136 or external memory 138.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The audio output module 155 may output sound signals to the outside of the electronic device 101. The audio output module 155 may include, for example, a speaker or a receiver. The speaker may be used for general purposes, such as playing multimedia or playing record. The receiver may be used for receiving incoming calls. The receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. The display module 160 may include a touch sensor adapted to detect a touch, or a pressure sensor adapted to measure the intensity of force incurred by the touch.

The audio module 170 may convert a sound into an electrical signal and vice versa. The audio module 170 may obtain the sound via the input module 150, or output the sound via the audio output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. The sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. The interface 177 may include, for example, a high definition multimedia interface (HDMI), a universal serial bus (USB) interface, a secure digital (SD) card interface, or an audio interface.

A connection terminal 178 may include a connector via which the electronic device 101 may be physically connected with the external electronic device (e.g., the electronic device 102). The connection terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. The haptic module 179 may include, for example, a motor, a piezoelectric element, or an electric stimulator.

The camera module 180 may capture a still image or moving images. The camera module 180 may include one or more lenses, image sensors, image signal processors, or flashes.

The power management module 188 may manage power supplied to the electronic device 101. The power management module 188 may be implemented as at least part of, for example, a power management integrated circuit (PMIC).

The battery 189 may supply power to at least one component of the electronic device 101. The battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the AP) and supports a direct (e.g., wired) communication or a wireless communication. The communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or a standard of the Infrared Data Association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. The antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. Another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

Commands or data may be transmitted or received between the electronic device 101 and the external electronic device 104 via the server 108 coupled with the second network 199. Each of the electronic devices 102 or 104 may be a device of a same type as, or a different type, from the electronic device 101. All or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

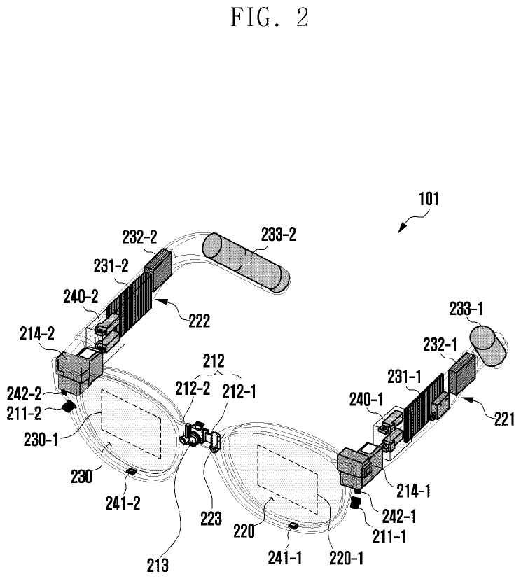

FIG. 2 is an overall configuration diagram of an electronic device (e.g., the electronic device 101 of FIG. 1, a wearable device, and/or wearable glasses) including a plurality of batteries and a plurality of current control modules for the respective batteries according to various example embodiments. Each current control module herein may comprise circuitry.

Referring to FIG. 2, in various embodiments, the electronic device 101 may be the electronic device 101 manufactured in a form of being worn on a head part of a user to provide an image related to an augmented reality service to the user. For example, the electronic device 101 may be configured in the form of at least one of glasses, goggles, a helmet, or a hat, but is not limited thereto.

According to an embodiment, the electronic device 101 may provide an image related to an augmented reality (AR) service which outputs at least one virtual object to be superimposed, based on an area determined as a field of view (FoV) of a user. For example, the area determined as the field of view (FoV) of the user may be an area including the entire or at least a part of a display module (e.g., the display module 160 of FIG. 1) of the electronic device 101, as an area determined to be recognized by a user wearing the electronic device 101 through the electronic device 101. According to an embodiment, the electronic device 101 may include a plurality of transparent members (e.g., a first transparent member 220 and/or a second transparent member 230) corresponding to both eyes (e.g., the left and/or right eye) of a user, respectively. The plurality of transparent members may include at least a part of the display module (e.g., the display module 160 of FIG. 1). For example, the first transparent member 220 corresponding to the left eye of a user may include a first display module, and the second transparent member 230 corresponding to the right eye of the user may include a second display module. The first display module and the second display module may be configured substantially the same and included in the display module 160.

Referring to FIG. 2, the electronic device 101 may include at least one transparent member (e.g., the first transparent member 220 and the second transparent member 230), at least one display module (e.g., a first display module 214-1 and a second display module 214-2), a camera module (e.g., the camera module 180 of FIG. 1), an audio module (e.g., the audio module 170 of FIG. 1), a first support portion 221, and/or a second support portion 222. According to an embodiment, the camera module 180 may include a capturing camera 213 for capturing an image corresponding to a field of view (FoV) of a user and/or measuring a distance from an object, an eye tracking camera 212 for identifying a direction of a user's gaze, and/or recognition cameras (gesture cameras) 211-1 and 211-2 for recognizing a predetermined space. According to an embodiment, the first support portion 221 and/or the second support portion 222 may at least partially include printed circuit boards (PCBs) 231-1 and 231-2, speakers 232-1 and 232-2, and/or batteries 233-1 and 233-2.

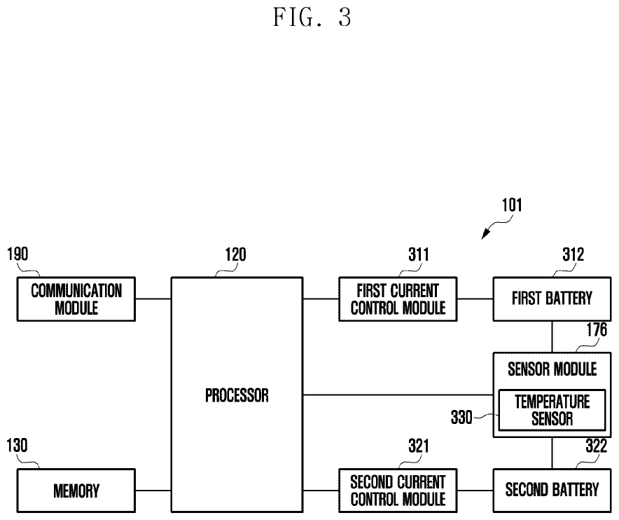

Referring to FIG. 2, the electronic device 101 may be configured by a body portion 223, a support portion (e.g., the first support portion 221 and/or the second support portion 222), and/or hinge portions (e.g., a first hinge portion 240-1 and a second hinge portion 240-2), and the body portion 223 and the support portions 221 and 222 may be operatively connected through the hinge portions 240-1 and 240-2. The body portion 223 may include the first transparent member 220, the second transparent member 230, and/or at least one camera (e.g., the recognition cameras 211-1 and 211-2, the eye tracking camera 212, and the capturing camera 213). The body portion 223 may be at least partially mounted on a user's nose, and may at least partially include the display module 160 and a camera module (e.g., the camera module 180 of FIG. 1). The support portions 221 and 222 may include support members mounted on ears of a user, and may include the first support portion 221 mounted on the left ear and/or the second support portion 222 mounted on the right ear. According to an embodiment, the first support portion 221 or the second support portion 222 may at least partially include a battery (e.g., a first battery 233-1 and/or a second battery 233-2) (e.g., the battery of FIG. 1). The batteries 233-1 and 233-2 may be electrically connected to a power management module (e.g., the power management module 188 of FIG. 1). According to an embodiment, the first battery 233-1 (e.g., a first battery 312 of FIG. 3) may be electrically connected to a first current control module (e.g., a first current control module 311 of FIG. 3, which may comprise circuitry) for at least partially controlling a current discharged from the first battery 233-1. The second battery 233-2 (e.g., a second battery 322 of FIG. 3) may be electrically connected to a second current control module (e.g., a second current control module 321 of FIG. 3, which may comprise circuitry) for at least partially controlling a current discharged from the second battery 233-2. According to an embodiment, the electronic device 101 may include the plurality of batteries 233-1 and 233-2 and a first current control module and/or a second current control module corresponding to the batteries, respectively. For example, the plurality of current control modules may be individually disposed on the plurality of printed circuit boards 231-1 and 231-2, and may at least partially control a current discharged from the plurality of batteries.

According to an embodiment, the first hinge portion 240-1 may connect the first support portion 221 and the body portion 223 so that the first support portion 221 is rotatable with respect to the body portion 223. The second hinge portion 240-2 may connect the second support portion 222 and the body portion 223 so that the second support portion 222 is rotatable with respect to the body portion 223. According to another embodiment, the hinge potions 240-1 and 240-2 of the electronic device 101 may be omitted. For example, the body portion 223 and the support portions 221 and 222 may be directly connected to each other.

The electronic device 101 of FIG. 2 may display information by projecting light generated by the display modules 214-1 and 214-2 onto transparent members (e.g., the first transparent member 220 and the second transparent member 230). For example, the light generated by the first display module 214-1 may be projected onto the first transparent member 220, and the light generated by the second display module 214-2 may be projected onto the second transparent member 230. As light capable of displaying virtual objects is projected onto the transparent members 220 and 230 at least partially made of a transparent material, a user can perceive a reality in which the virtual objects overlap. In this case, the display module 160 described in FIG. 1 may be understood to include the display modules 214-1 and 214-2 and the transparent members 220 and 230 in the electronic device 200 shown in FIG. 2. However, the electronic device 101 described in the disclosure is not limited to displaying information through the manner described above. A display module which may be included in the electronic device 101 may be changed to a display module including various information display methods. For example, when a display panel including a light-emitting element made of a transparent material is embedded in the transparent members 220 and 230 itself, information may be displayed without a separate display module (e.g., the first display module 214-1 and the second display module 214-2). In this case, the display module 160 described in FIG. 1 may refer to the transparent members 220 and 230 and a display panel included in the transparent members 220 and 230.

According to an embodiment, a virtual object output through the display modules 214-1 and 214-2 may include information related to an application program executed in the electronic device 101 and/or information related to an external object located in a real space recognized by a user through the transparent members 220 and 230. The external object may include an object existing in the real space. Hereinafter, the real space recognized by the user through the transparent members 220 and 230 will be referred to as a field of view (FoV) area of the user. For example, the electronic device 200 may identify an external object included in at least a part of an area determined as the field of view (FoV) of the user in image information related to the real space acquired through a camera module (e.g., the capturing camera module 213) of the electronic device 200. The electronic device 200 may output a virtual object related to the identified external object through the display modules 214-1 and 214-2.

According to an embodiment, the display module 160 may include the first transparent member 220 and the second transparent member 230, and provide visual information to a user through the first transparent member 220 and the second transparent member 230. The electronic device 101 may include the first transparent member 220 corresponding to the left eye and/or the second transparent member 230 corresponding to the right eye. According to an embodiment, the display module 160 may include a display panel, a protection panel (e.g., a protection layer), and/or a lens. For example, the display panel may include a transparent material such as glass or plastic.

According to an embodiment, a transparent member (e.g., the first transparent member 220 and the second transparent member 230) may include a condensing lens (not shown) and/or a waveguide (not shown) (e.g., a display area (e.g., a display area 220-1 and/or a display area 230-1) which includes a waveguide (e.g., an RGB waveguide) for displaying a virtual object, and/or a waveguide (e.g., an IR waveguide) for transmitting infrared ray (IR) light and in which a virtual object is displayed. For example, the display area 220-1 may be partially located on the first transparent member 220, and the display area 230-1 may be partially located on the second transparent member 230. According to an embodiment, light emitted from the display modules 214-1 and 214-2 may be incident on one surfaces of the display areas 220-1 and 230-1 included in the transparent members 220 and 230. The light incident on the one surfaces of the display areas 220-1 and 230-1 included in the transparent members 220 and 230 may be transmitted to a user through a waveguide (not shown) located in the display areas 220-1 and 230-1. For example, the waveguide included in the display areas 220-1 and 230-1 may be made of glass, plastic, or polymer, and may include a nano-pattern formed on an inner or outer surface thereof. For example, the nano-pattern may include a polygonal or curved grating structure. According to an embodiment, the light incident on the one surfaces of the display areas 220-1 and 230-1 included in the transparent members 220 and 230 may be propagated or reflected inside the waveguide by the nano-pattern to be transmitted to the user. According to an embodiment, the waveguide included in the display areas 220-1 and 230-1 may include at least one of at least one diffractive element (e.g., a diffractive optical element (DOE) and a holographic optical element (HOE)) or a reflective element (e.g., a reflective mirror). According to an embodiment, the waveguide included in the display areas 220-1 and 230-1 may guide the light emitted from the display modules 214-1 and 214-2 to pupils of the user by using the at least one diffractive element or reflective element.

According to an embodiment, the first transparent member 220 and/or the second transparent member 230 included in the display module 160 may be divided into a first display area and a second display area. For example, the first display area may be an area where an augmented reality service is provided to a user, and may include the display areas 220-1 and 230-1. The second display area may be included in at least one transparent member 220 and 230 and may be a remaining area other than the first display area (e.g., the display areas 220-1 and 230-1). According to an embodiment, the user may see a real object and a virtual object generated by an augmented reality service, based on the first display area and the second display area.

According to an embodiment, the electronic device 101 may provide an augmented reality service for the first display area (e.g., the display areas 220-1 and 230-1) by using the first battery 233-1 included in the first support portion 221 and the second battery 233-2 included in the second support portion 222. The electronic device 101 may provide an augmented reality service by integrating an amount of current discharged from the first battery 233-1 and the second battery 233-2. According to another embodiment, the electronic device 101 may independently operate each of a first current discharged from the first battery 233-1 and a second current discharged from the second battery 233-2. For example, the electronic device 101 may individually provide an augmented reality service for the left display area 220-1, based on the first current, and provide an augmented reality service for the right display area 230-1, based on the second current.

According to an embodiment, the waveguide may be classified as a waveguide (e.g., an RGB waveguide) for displaying a virtual object according to an augmented reality service, based on the first display area, and a waveguide (e.g., an IR waveguide) for transmitting IR light (e.g., infrared rays), based on the second display area. According to an embodiment, the electronic device 101 may provide a virtual object to a user through a waveguide disposed in the first display area. For example, the first display area may be an area where a virtual object is displayed. According to an embodiment, the electronic device 101 may track a user's gaze through a waveguide disposed in the second display area. For example, the second display area may be an area where a virtual object is not displayed, and a real object may be displayed in the area.

According to an embodiment, the first display area (e.g., the display areas 220-1 and 230-1) may be an area where at least one object related to an augmented reality service is displayed, based on the light emitted, through a waveguide (e.g., an RGB waveguide) located on at least a part of the transparent members 220 and 230.

According to an embodiment, even when light generated from a light source module (not shown) is reflected by a pattern formed on a waveguide (e.g., an IR waveguide) located in the second display area and thus reflected from pupils of a user, the user may not substantially detect the emitted light. Since light (e.g., infrared rays or IR light) emitted from a light source module 310, comprising a light source, is transmitted to the pupils of the user, based on a waveguide (not shown) disposed in the second display area, the user may not detect a situation in which the light is transmitted. According to an embodiment, the electronic device 101 may detect movement (e.g., gaze) of the pupils of the user, based on the light transmitted to the pupils of the user.

According to another embodiment, the first transparent member 220 and/or the second transparent member 230 may be configured by a transparent element, and allow a user to recognize a real space of a rear surface thereof through the first transparent member 220 and/or the second transparent member 230. The first transparent member 220 and/or the second transparent member 230 may display a virtual object on at least a partial area (e.g., the display areas 220-1 and 230-1) of the transparent element such that the user sees that a virtual object is added to at least a part of the real space. The first transparent member 220 and/or the second transparent member 230 may include a plurality of panels to correspond to both eyes (e.g., the left eye and/or the right eye) of the user, respectively. According to another embodiment, when the first transparent member 220 and/or the second transparent member 230 are transparent uLEDs, the waveguide configuration in the transparent members may be omitted. According to an embodiment, the electronic device 101 may include a virtual reality (VR) device (e.g., a virtual reality device).

Referring to FIG. 2, the first support portion 221 and/or the second support portion 222 may include the printed circuit boards 231-1 and 231-2 for transmitting an electrical signal to each component of the electronic device 101, the speakers 232-1 and 232-2 for outputting an audio signal, the batteries 233-1 and 233-2, and/or the hinge portions 240-1 and 240-2 for at least partially coupling to the body portion 223 of the electronic device 101. According to an embodiment, the speakers 232-1 and 232-2 may include a first speaker 232-1 for transmitting an audio signal to the left ear of a user, and a second speaker 232-2 for transmitting an audio signal to the right ear of the user. The speakers 232-1 and 232-2 may be included in the audio module 170 of FIG. 1. According to an embodiment, the electronic device 101 may include a plurality of batteries (e.g., the first battery 233-1 and/or the second battery 233-2), and supply power to a printed circuit board (e.g., a first printed circuit board 231-1 and/or a second printed circuit board 231-2) through a power management module (e.g., the power management module 188 of FIG. 1). According to an embodiment, the electronic device 101 may include a first current control module (e.g., the first current control module 311 of FIG. 3) for controlling a first current discharged from the first battery 233-1 and/or a second current control module (e.g., the second current control module 321 of FIG. 3) for controlling a second current discharged from the second battery 233-2. For example, the first current control module 311 may be disposed on the first printed circuit board 231-1 and electrically connected to the first battery 233-1. The second current control module 321 may be disposed on the second printed circuit board 231-2 and electrically connected to the second battery 233-2.

Referring to FIG. 2, the electronic device 101 may include a microphone 241 for receiving a user's voice and ambient sound. For example, the microphone 241 may be included in the audio module 170 of FIG. 1. The electronic device 101 may include an illuminance sensor 242 for identifying ambient brightness. For example, the illuminance sensor 242 may be included in the sensor module 176 of FIG. 1, comprising at least one sensor. According to an embodiment, the electronic device 101 may include a temperature sensor (e.g., a temperature sensor 330 of FIG. 3) for measuring a temperature of each of the first battery 233-1 and/or the second battery 233-2. For example, the temperature sensor 330 may include a first temperature sensor for measuring a temperature of the first battery 233-1 and/or a second temperature sensor for measuring a temperature of the second battery 233-2. According to an embodiment, the electronic device 101 may individually identify a temperature change of the first battery 233-1 and/or a temperature change of the second battery 233-2. The electronic device 101 may identify a temperature change of each of the plurality of batteries and at least partially adjust an amount of current discharged from the plurality of batteries.

According to an embodiment, the electronic device 101 may measure a temperature of the first battery 233-1 and identify whether the measured temperature exceeds a preconfigured threshold value. For example, when the temperature of the first battery 233-1 exceeds a threshold value, the electronic device may determine that the first battery 233-1 is operating abnormally. When the temperature of the first battery 233-1 exceeds the threshold value, the electronic device 101 may reduce an amount of a first current discharged from the first battery 233-1 by using the first current control module 311. According to an embodiment, when the temperature of the second battery 233-2 does not exceed the threshold value in a state where the temperature of the first battery 233-1 exceeds the threshold value, the electronic device 101 may increase an amount of a second current discharged from the second battery 233-2 by using the second current control module 321. For example, the second current control module 321 may at least partially control the second battery 233-2 so that a current (e.g., the second current) which can be supplied by the second battery 233-2 is discharged. For example, the current which can be supplied by the second battery 233-2 may be previously configured. According to an embodiment, the electronic device 101 may integrate the first current and the second current into a total amount of current, and at least partially control at least one configuration (e.g., a system), based on the total amount of current.

FIG. 3 is a block diagram of an electronic device including a plurality of current control modules for managing a plurality of batteries according to various example embodiments.

An electronic device (e.g., the electronic device 101 of FIG. 1) of FIG. 3 may be at least partially similar to the electronic device 101 (e.g., an AR device or a wearable electronic device) of FIG. 2, or may further include other embodiments of the electronic device 101.

According to an embodiment, the electronic device 101 may include an augmented reality (AR) electronic device which is worn on a user's head part and provides an augmented reality service. For example, the electronic device 101 may be configured in the form of at least one of glasses, goggles, a helmet, or a hat, but is not limited thereto.

Referring to FIG. 3, the electronic device 101 may include a processor (e.g., the processor 120 of FIG. 1), a memory (e.g., the memory 130 of FIG. 1), a sensor module (e.g., the sensor module 176 of FIG. 1), a communication module (e.g., the communication module 190 of FIG. 1, comprising communication circuitry), a plurality of batteries (e.g., the first battery 312 and/or the second battery 322), and a plurality of current control modules (e.g., the first current control module 311 and/or the second current control module 321, each comprising control circuitry) for controlling an amount of current discharged from the plurality of batteries.

The processor 120 may execute a program (e.g., the program 140 of FIG. 1) stored in the memory 130 so as to control at least one other component (e.g., a hardware or software component), and perform various data processing or calculations. For example, the processor 120 may measure temperatures of the plurality of batteries (e.g., the first battery 312 and/or the second battery 322) by using the temperature sensor 330 included in the sensor module 176, and individually control an amount of current discharged from the plurality of batteries, based on the measured temperatures. For example, the processor 120 may adjust an amount of a first current (e.g., a first discharge current) discharged from the first battery 312 by using the first current control module 311, and adjust an amount of a second current (e.g., a second discharge current) discharged from the second battery 322 by using the second current control module 321. The processor 120 may individually control a discharge current of each battery.

The memory 130 may store at least one preconfigured threshold value in order to identify a temperature change of the first battery 312 and the second battery 322. For example, when the temperature of a battery rises above a predetermined level (e.g., when the temperature difference between the first battery 312 and the second battery 322 exceeds a configured reference value), the processor 120 may identify that the battery is operating abnormally. A temperature value above the predetermined level may be stored in the memory 130 as at least one threshold value. For example, the processor 120 may be in a state where a first threshold value and a second threshold value for a temperature of the first battery 312 are stored in the memory 130. The processor 120 may adjust a current discharged from the first battery 312 to a first current when the temperature of the first battery 312 exceeds the first threshold value, and adjust the current discharged from the first battery 312 to a second current when the temperature of the first battery 312 exceeds the second threshold value. According to an embodiment, the electronic device 101 may adjust the amount of current discharged from the battery such that the larger the temperature increase of the battery becomes, the smaller the amount of current discharged from the battery becomes.

The sensor module 176 may include the temperature sensor 330 for measuring a temperature change of the first battery 312 and/or the second battery 322. For example, the temperature sensor 330 may include a first temperature sensor for measuring a temperature of the first battery 312 and a second temperature sensor for measuring a temperature of the second battery 322. The temperature sensor 330 may be disposed at least partially adjacent to the first battery 312 and the second battery 322, and may periodically provide, to the processor 120, a temperature change amount of each of the plurality of batteries.

The communication module 190, comprising communication circuitry, may support establishment of a direct (e.g., wired) communication channel or a wireless communication channel between the electronic device 101 and an external electronic device (e.g., the electronic device 102, the electronic device 104, or the server 108), and performing communication through the established communication channel. For example, the processor 120 may communicate with the external electronic device 102 through the communication module 190, based on the first current discharged from the first battery 312 and the second current discharged from the second battery 322. According to an embodiment, the processor 120 may reduce current consumption through the communication module 190 when a total amount of current based on the first current and/or the second current decreases. For example, the processor 120 may lower performance of communication with the external electronic device 102, or stop the communication.

The first current control module 311 may at least partially control the first current discharged from the first battery 312, and the second current control module 321 may at least partially control the second current discharged from the second battery 322. For example, the first current control module 311 and/or the second current control module 321 may include a limiter circuit which performs a control to increase or decrease a discharge current of a battery. The limiter circuit may adjust an output voltage (e.g., a discharge current) of a battery. The first current control module 311 may adjust a discharge current (e.g., a first discharge current) of the first battery 312 while being electrically connected, directly or indirectly, to the first battery 312, and the second current control module 321 may adjust a discharge current (e.g., a second discharge current) of the second battery 322 while being electrically connected, directly or indirectly, to the second battery 322. According to an embodiment, the electronic device 101 may include the plurality of batteries and the plurality of current control modules corresponding to the plurality of batteries, respectively, and individually manage the plurality of batteries. For example, the first current control module 311 and/or the second current control module 321 may perform a control to increase or decrease an amount of current discharged from the battery. According to an embodiment, the processor 120 may adjust a first discharge current of the first battery 312 by using the first current control module 311, and adjust a second discharge current of the second battery 322 by using the second current control module 321. The processor 120 may manage a total discharge current (e.g., a total amount of current) based on the first discharge current and the second discharge current to be adjusted to a predetermined level. According to another embodiment, the first current control module 311 and/or the second current control module 321 may include a fuel gauge module (e.g., a battery capacity measurement module) for measuring a residual capacity of the battery. For example, the processor 120 may identify a residual capacity of the first battery 312 through a first battery capacity measurement module included in the first current control module 311, and identify a residual capacity of the second battery 322 through a second battery capacity measurement module included in the second current control module 321.

The first battery 312 may discharge (e.g., supply) a first current to the processor 120 through the first current control module 311, and the second battery 322 may discharge (e.g., supply) a second current to the processor 120 through the second current control module 321. The temperature of the first battery 312 and/or the second battery 322 may be changed according to an operation situation of the electronic device 101. For example, a temperature of a battery may increase excessively in a situation in which the battery burns out, in a situation in which the battery is short-circuited, and/or in a situation in which the battery is over-discharged. According to an embodiment, the processor 120 may measure a temperature of a battery, and identify that a problem has occurred in the battery when the measured temperature rises beyond a predetermined threshold value. The processor 120 may perform a control to increase or decrease an amount of current discharged from the battery. According to an embodiment, the electronic device 101 may integrate and manage a current discharged from each of the first battery 312 and the second battery 322, and at least partially limit functions of at least one component, based on the current. According to an embodiment, the processor 120 may be in a state of being connected in parallel with the first battery 312 and the second battery 322.

According to an embodiment, the processor 120 of the electronic device 101 may periodically measure temperatures of the first battery 312 and/or the second battery 322 by using the temperature sensor 330 included in the sensor module 176. The processor 120 may identify an amount of change in the temperature of each battery, and identify that a problem has occurred in the operation of the battery when the identified amount of change in the temperature exceeds a predetermined threshold value. According to an embodiment, the temperature sensor 330 may be disposed to correspond to a predetermined part of the electronic device 101 that is in contact with the human body when the electronic device is worn. When a temperature change amount of a battery exceeds a threshold value, the processor 120 may adjust a current discharged from the corresponding battery to decrease. For example, when a temperature change amount of the first battery 312 exceeds the threshold value, the processor 120 may adjust a first current discharged from the first battery 312 to decrease, through the first current control module 311. For example, when a temperature change amount of the second battery 322 does not exceed the threshold value, the processor 120 may adjust a second current discharged from the second battery 322 to increase, through the second current control module 321. The processor 120 may adjust the first current and the second current so that a total amount of current provided to the electronic device 101 is maintained constant.

According to an embodiment, the processor 120 may store a plurality of threshold values differentially configured in the memory 130, and adjust an amount of current discharged from a battery such that the larger the temperature change amount of the battery becomes, the larger the amount of current discharged from the battery becomes. For example, when the temperature change amount of the first battery 312 exceeds the first threshold value, the processor 120 may perform a control such that the first current is discharged from the first battery 312, and when the temperature change amount of the first battery 312 exceeds the second threshold value, the processor 120 may perform a control such that the second current is discharged from the first battery 312. The second threshold value may be configured to be higher than the first threshold value, and the second current may be configured to be a lower value than the first current. For example, when the temperature of a battery rises beyond the threshold value, the processor 120 may adjust a discharge current of the battery to decrease.

According to various embodiments, the electronic device 101 may include the first battery 312, the second battery 322 connected, directly or indirectly, in parallel with the first battery 312, the first current control module 311 for controlling a first discharge current of the first battery 312, the second current control module 321 for controlling a second discharge current of the second battery 322, the sensor module 176 for sensing a temperature of the first battery 312 and a temperature of the second battery 322, the memory 130, and the processor 120 operatively connected, directly or indirectly, to the first current control module 311, the second current control module 321, the sensor module 176, and the memory 130. The processor 120 may measure a temperature of the first battery 312 and a temperature of the second battery 322 by using the sensor module 176, identify whether at least one reference condition is satisfied, based on the temperature of the first battery 312 and the temperature of the second battery 322, control a first discharge current of the first battery 312 by using the first current control module 311 when the at least one reference condition is satisfied, and control a second discharge current of the second battery 322 by using the second current control module 321.

According to an embodiment, the processor 120 may calculate a difference value between the temperature of the first battery 312 and the temperature of the second battery 322 to identify whether the difference value exceeds a configured reference value, or identify whether at least one of the temperature of the first battery and the temperature of the second battery exceeds a configured absolute reference value, and identify that the at least one reference condition is satisfied, when the difference value exceeds the reference value or at least one of the temperature of the first battery and the temperature of the second battery exceeds the absolute reference value.

According to an embodiment, the processor 120 may identify a battery of which the temperature has risen relatively higher among the first battery 312 and the second battery 322 when it is identified that the at least one reference condition is satisfied, and configure a discharge current of the identified battery to be low, by using a current control module corresponding to the identified battery.

According to an embodiment, the processor 120 may configure the first discharge current of the first battery 312 to be low by using the first current control module 311, when the temperature of the first battery 312 has risen higher than the temperature of the second battery 322 and thus the difference value exceeds the configured reference value, and configure the second discharge current of the second battery 322 to be high by using the second current control module 321, when the temperature of the first battery 312 has risen higher than the temperature of the second battery 322 and thus the difference value exceeds the configured reference value.

According to an embodiment, the processor 120 may configure the second discharge current of the second battery 322 to be a current value supportable by the second battery 322.

According to an embodiment, the reference value includes a first reference value and a second reference value, the absolute reference value includes a first absolute reference value and a second absolute reference value, the second reference value is relatively greater than the first reference value, and the second absolute reference value is relatively greater than the first absolute reference value.

According to an embodiment, a discharge current of the first battery 312 when the difference value exceeds the first reference value in a situation in which the temperature of the first battery 312 is relatively higher than the temperature of the second battery 322 is greater than a discharge current of the first battery 312 when the difference value exceeds the second reference value.

According to an embodiment, a discharge current determined based on the first absolute reference value is greater than a discharge current determined based on the second absolute reference value.

According to an embodiment, the processor 120 may identify a total amount of current supplied to a system of the electronic device 101, based on the first discharge current and the second discharge current, and at least partially limit functions of the system, based on the identified total amount of current.

According to an embodiment, the sensor module 176 may include a first temperature sensor for sensing a temperature of the first battery 312 and a second temperature sensor for sensing a temperature of the second battery 322, and the processor 120 may individually measure a temperature of the first battery 312 through the first temperature sensor, and a temperature of the second battery 322 through the second temperature sensor.

According to an embodiment, the first current control module 311 may include a first battery capacity measurement module for measuring a residual capacity of the first battery 312, and the second current control module 321 may include a second battery capacity measurement module for measuring a residual capacity of the second battery 322.

According to an embodiment, the processor 120 may measure a residual capacity of the first battery 312 by using the first battery capacity measurement module (comprising circuitry), and determine a first discharge current of the first battery 312 by using the first current control module 311, based on the measured residual capacity of the first battery 312.

According to an embodiment, the processor 120 may measure a residual capacity of the second battery 322 by using the second battery capacity measurement module (comprising circuitry), and determine a second discharge current of the second battery 322 by using the second current control module 321, based on the measured residual capacity of the second battery 322.

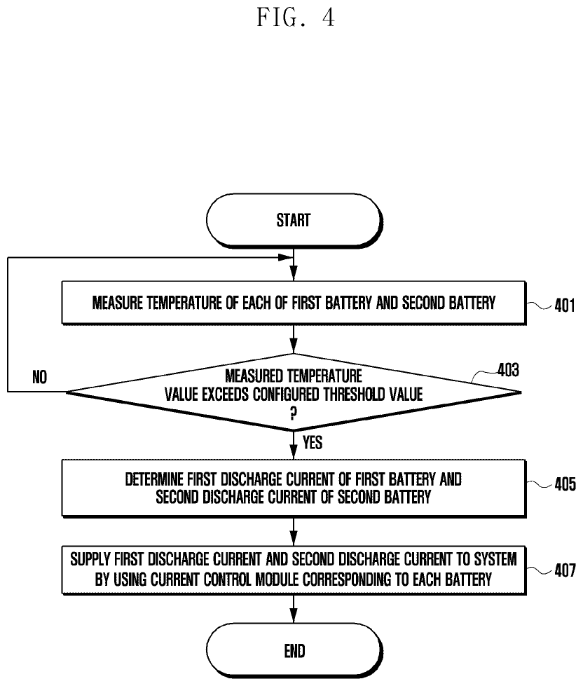

FIG. 4 is a flowchart illustrating a method for controlling an amount of current discharged from a plurality of batteries according to various example embodiments.

An electronic device (e.g., the electronic device 101 of FIG. 1) of FIG. 4 may be at least partially similar to the electronic device 101 (e.g., an AR device or a wearable electronic device) of FIG. 2, or may further include other embodiments of the electronic device 101. The electronic device 101 of FIG. 4 may include at least one component shown in FIG. 3.

In operation 401, a processor (e.g., the processor 120 of FIG. 1) of the electronic device 101 may measure temperatures of a first battery (e.g., the first battery 312 of FIG. 3) and a second battery (e.g., the second battery 322 of FIG. 3). For example, the processor 120 may measure the temperature of the first battery 312 and the temperature of the second battery 322 according to a configured period by using a temperature sensor (e.g., the temperature sensor 330 of FIG. 3). The processor 120 may continuously identify a temperature value of a battery in real time. According to an embodiment, the processor 120 may calculate a difference value between the first battery 312 and the second battery 322. For example, the processor 120 may identify a battery of which the temperature has risen relatively among the first battery 312 and the second battery 322.

In operation 403, the processor 120 may identify whether the measured temperature value exceeds a configured threshold value. For example, at least one configured threshold value is stored in the memory 130, and the processor 120 may identify whether temperature values of the first battery 312 and the second battery 322 has risen to a level exceeding the threshold value. For example, the processor 120 may identify whether the difference value exceeds a configured reference value (e.g., a first reference value, a second reference value, or a third reference value), based on the difference value between the first battery 312 and the second battery 322. For example, a plurality of reference values may be configured according to the degree to which the difference value increases. When the temperature of the first battery 312 rises, the processor 120 may determine the decrease of a first discharge current of the first battery 312 such that the larger the temperature increase becomes, the larger the decrease of the first discharge current of the first battery becomes. According to an embodiment, the processor 120 may identify a battery of which the temperature has risen relatively higher among the first battery 312 and the second battery 322, and determine to reduce a discharge current of the battery of which the temperature has risen high.

In operation 405, the processor 120 may determine a first discharge current of the first battery 312 and a second discharge current of the second battery 322. For example, the first discharge current refers to an amount of current discharged from the first battery 312, and the second discharge current refers to an amount of current discharged from the second battery 322. When the temperature of a battery rises beyond the threshold value (e.g., when a difference value between the temperature of the first battery 312 and the temperature of the second battery 322 rises beyond the configured reference value), the processor 120 may determine to reduce the discharge current of the battery of which the temperature has risen. According to an embodiment, in a state in which the temperature of the first battery 312 exceeds the configured threshold value and the temperature of the second battery 322 is lower than the configured threshold value, the processor 120 may determine to reduce the first discharge current of the first battery 312 and to raise the second discharge current of the second battery 322. For example, the processor 120 may determine the first discharge current and the second discharge current so that a total current value of the electronic device 101 is maintained constant, based on the first discharge current and the second discharge current.

In operation 407, the processor 120 may supply the first discharge current and the second discharge current to a system by using a current control module (e.g., the first current control module 311 of FIG. 3 and/or the second current control module 321 of FIG. 3, each comprising control circuitry) corresponding to each battery (e.g., the first battery 312 and/or the second battery 322). According to an embodiment, the processor 120 may integrate the first discharge current and the second discharge current to supply the same to the system, and maintain an operation of the system for the electronic device 101. According to an embodiment, in a state in which an amount of current required to drive the system is configured, the electronic device 101 may maintain the operation of the system when the integrated total current amount of the first discharge current and the second discharge current satisfies the required amount of current. For example, when the total amount of current is less than the required amount of current, the processor 120 may at least partially limit, or stop functions of at least one component.

According to an embodiment, the electronic device 101 may measure a temperature of each of a plurality of batteries (e.g., the first battery 312 and/or the second battery 322), and adjust a discharge current of the corresponding battery to decrease when the measured temperature exceeds a configured threshold value. According to an embodiment, the electronic device 101 may include a current control module (e.g., the first current control module 311 and/or the second current control module 321) corresponding to each battery (e.g., the first battery 312 and/or the second battery 322), and adjust a discharge current of a battery under the control of the current control module. According to an embodiment, when the discharge current is adjusted to decrease, the electronic device 101 may at least partially limit, or stop functions of at least one component, based on the discharge current. According to an embodiment, the electronic device 101 may calculate a difference value between the temperature of the first battery 312 and the temperature of the second battery 322, and when the difference value exceeds a configured reference value, determine to reduce the first discharge current of the first battery 312 of which the temperature has risen relatively. The electronic device 101 may determine to relatively raise the second discharge current of the second battery 322. For example, the second discharge current may include a maximum or large discharge current of the second battery 322.

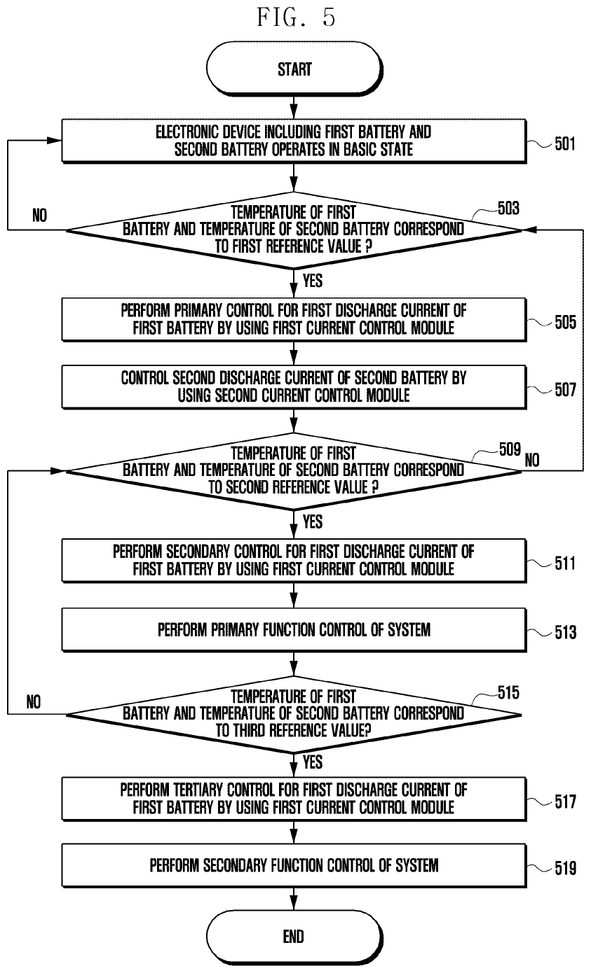

FIG. 5 is a flowchart illustrating a method for measuring temperatures of a plurality of batteries and controlling an amount of current discharged from the plurality of batteries, based on the measured temperatures, according to various example embodiments.

An electronic device (e.g., the electronic device 101 of FIG. 1) of FIG. 5 may be at least partially similar to the electronic device 101 (e.g., an AR device or a wearable electronic device) of FIG. 2, or may further include other embodiments of the electronic device 101. The electronic device 101 of FIG. 5 may include at least one component shown in FIG. 3.

In operation 501, the electronic device 101 including a plurality of batteries (e.g., the first battery 312 of FIG. 3, and the second battery 322 of FIG. 3) may operate in a basic state (e.g., a default state). For example, the processor 120 (comprising processing circuitry) of the electronic device 101 may receive a discharge current supplied based on the first battery 312 and the second battery 322, and perform a function of at least one component (e.g., a system) by using the supplied discharge current. For example, the processor 120 may operate the system of the electronic device 101, based on a first current discharged from the first battery 312 and a second current discharged from the second battery 322. In operation 501, the electronic device 101 operates in a basic state (e.g., a default state), and the basic state may include a case where a temperature difference with respect to the batteries is about 3 degrees or less or an absolute temperature is about 38 degrees or less. For example, the basic state may be a state in which the temperature difference between the first battery 312 and the second battery 322 is about 3 degrees or less and a state in which an absolute temperature of each of the first battery 312 and the second battery 322 is about 38 degrees or less. The electronic device 101 in the basic state may be in a state in which a first reference value is not satisfied. For example, when the electronic device 101 operates in the basic state, the first current and the second current may be determined to be substantially the same current value. When a total amount of current consumed by the electronic device 101 in the basic state is about 500 mA, each of the first current and the second current may be determined to be about 250 mA. In the following description, it is described that the electronic device 101 in the basic state has a first current and a second current of about 250 mA, but is not limited thereto. The processor 120 may individually measure temperatures of the plurality of batteries (e.g., the first battery 312 and the second battery 322), according to a configured period, by using a temperature sensor (e.g., the temperature sensor 330 of FIG. 3).

According to an embodiment, the electronic device 101 may configure at least one reference value (e.g., a first reference value, a second reference value, and/or a third reference value), based on the first battery 312 and the second battery 322, and store the at least one reference value in the memory 130. (Table 1) below shows reference values related to temperatures of the first battery 312 and the second battery 322.

TABLE 1

| | | Measured temperature |
|---|---|---|
| | Temperature difference | (e.g., absolute |
| | between first battery | temperature) of each |
| | and second battery | battery |
| Basic state | About 3 degrees or less | About 38 degrees or less |
| (default state) | | |
| First reference | Range of about 3-6 | Range of about 38-40 |
| value | degrees | degrees |
| Second reference | Range of about 6-10 | Range of about 40-42 |
| value | degrees | degrees |
| Third reference | About 10 degrees or | About 42 degrees or |
| value | more | more |

Referring to (Table 1), the processor 120 may measure a temperature of each of the first battery 312 and the second battery 322, and operate in the basic state when the temperature difference between the first battery 312 and the second battery 322 is about 3 degrees or less. The processor 120 may operate in the basic state when the temperature of each of the first battery 312 and/or the second battery 322 is about 38 degrees or less. For example, the basic state may include a state in which the measured temperature of the first battery 312 is about 38 degrees or less and the measured temperature of the second battery 322 is about 38 degrees or less. For example, the basic state may include a state in which a battery operates within a normal range. The processor 120 in the basic state may determine the first current and the second current as substantially the same current value. For another example, a state in which the first reference value is satisfied may refer to a state in which the temperature difference between the first battery 312 and the second battery 322 is included within the range of about 3 degrees to about 6 degrees. In addition, when the temperature of at least one of the first battery 312 and/or the second battery 322 is included within the range of about 38 degrees to about 40 degrees, the processor 120 may identify that the first reference value is satisfied.

According to an embodiment, when the temperature difference between the first battery 312 and the second battery 322 is included within the range of about 3-6 degrees, the processor 120 may identify that the first reference value is satisfied. When the temperature of at least one of the first battery 312 and/or the second battery 322 is included within the range of about 38-40 degrees, the processor 120 may identify that the first reference value is satisfied. When the first reference value is satisfied, the processor 120 may determine to reduce a discharge current of a battery having a relatively high temperature, and determine to raise a discharge current of a battery having a relatively low temperature. For example, when an absolute temperature of the first battery 312 is about 39 degrees and an absolute temperature of the second battery 322 is about 36 degrees, the processor 120 may configure a discharge current of the first battery 312 to be relatively low, and configure a discharge current of the second battery 322 to be relatively high. For example, when the first reference value is satisfied, the processor 120 may maintain a total amount of current based on the first battery 312 and the second battery 322 to be equal to a total amount of current in the basic state, and operate the system of the electronic device 101 substantially same as that in the basic state.

According to another embodiment, when the temperature difference between the first battery 312 and the second battery 322 is included within the range of about 6-10 degrees, the processor 120 may identify that the second reference value is satisfied. When the temperature of at least one of the first battery 312 and/or the second battery 322 is included within the range of about 40-42 degrees, the processor 120 may identify that the second reference value is satisfied. When the second reference value is satisfied, the processor 120 may determine to further reduce a discharge current of a battery having a relatively high temperature, and determine to further raise a discharge current of a battery having a relatively low temperature. For example, when the second reference value is satisfied, a total amount of current based on the first battery 312 and the second battery 322 may be lower than a total amount of current in the basic state, and the processor 120 may at least partially limit, or stop functions of the system (e.g., at least one component). (Primary function control)

According to another embodiment, when the temperature difference between the first battery 312 and the second battery 322 exceeds about 10 degrees, the processor 120 may identify that the third reference value is satisfied. When the temperature of at least one of the first battery 312 and/or the second battery 322 exceeds about 42 degrees, the processor 120 may identify that the third reference value is satisfied. When the third reference value is satisfied, the processor 120 may determine to further reduce a discharge current of a battery having a relatively high temperature, or cut off supply of the discharge current. For example, when the third reference value is satisfied, a total amount of current based on the first battery 312 and the second battery 322 may be lower than a total amount of current according to the second reference value, and the processor 120 may additionally further limit, or stop the functions of the system (e.g., at least one component). (Secondary function control)

According to an embodiment, the processor 120 may periodically measure temperatures of the first battery 312 and the second battery 322, and identify whether a reference value (e.g., the first reference value, the second reference value, and/or the third reference value) stored in the memory 130 is satisfied, based on the measured temperatures. When the reference value is satisfied, the processor 120 may determine a first discharge current of the first battery 312 and a second discharge current of the second battery 322, based on the satisfied reference value. For example, when the first reference value is satisfied, the processor 120 may operate based on a first amount of current substantially equal to a total amount of current in the basic state. When the second reference value is satisfied, the processor 120 may operate in a “primary function control” mode, and operate based on a second amount of current lower than the first amount of current. When the third reference value is satisfied, the processor 120 may operate in a “secondary function control” mode, and operate based on a third amount of current lower than the second amount of current. The “primary function control” mode may include a mode in which the function of the system (e.g., at least one component) of the electronic device 101 is at least partially limited. The “secondary function control” mode may include a mode in which the function of the system (e.g., at least one component) of the electronic device 101 is more/largely limited than the “first function control” mode.

According to an embodiment, a situation in which the reference value is satisfied may include a situation in which a battery operates abnormally (e.g., a situation in which the battery burns out, a situation in which the battery is shorted, and/or a situation in which the battery is over-discharged). When the battery operates abnormally, the processor 120 may adjust a temperature of the battery by controlling a discharge current of the battery.

In operation 503, the processor 120 may measure a temperature of each of the first battery 312 and the second battery 322, and identify whether the temperature of the first battery 312 and the temperature of the second battery 322 correspond to the first reference value. Referring to (Table 1), when a difference value between a first temperature value of the first battery 312 and a second temperature value of the second battery 322 is included within the range of about 3-6 degrees, the processor 120 may determine that the temperatures correspond to the first reference value. For another example, when at least one of the first temperature value of the first battery 312 and the second temperature value of the second battery 322 is included within the range of about 38-40 degrees (e.g., an absolute temperature), the processor 120 may determine that the temperatures correspond to the first reference value. A condition corresponding to the first reference value may include a (1-1)th condition in which the difference between the first temperature value and the second temperature value is included within the range of about 3-6 degrees, and a (1-2)th condition in which at least one of the first temperature value and the second temperature value is included within the range of about 38-40 degrees. The processor 120 may determine that the temperatures correspond to the first reference value when at least one of the (1-1)th condition and the (1-2)th condition is satisfied.

When the temperature of the first battery 312 and the temperature of the second battery 322 correspond to the first reference value in operation 503, in operation 505, the processor 120 may perform a primary control for the first discharge current of the first battery 312 by using a first current control module (e.g., the first current control module 311 of FIG. 3). For example, when the temperature of the first battery 312 rises by about 3-6 degrees higher than the temperature of the second battery 322, the processor 120 may control the first current control module 311 so that the first discharge current of the first battery 312 is lowered. For example, when a current of about 250 mA is discharged from the first battery 312 in the basic state of operation 501, in operation 505, the processor 120 may discharge a current of about 200 mA from the first battery 312 through the first current control module 311.

In operation 507, the processor 120 may control the second discharge current of the second battery 322 by using a second current control module (e.g., the second current control module 321 of FIG. 3). For example, when the temperature of the first battery 312 rises by about 3-6 degrees higher than the temperature of the second battery 322, the processor 120 may control the second current control module 321 so that the second discharge current of the second battery 322 rises while controlling the first current control module 311 so that the first discharge current of the first battery 312 is lowered. For example, the processor 120 may at least partially control the second discharge current so that a total amount of current based on the first battery 312 and the second battery 322 is maintained. For example, the processor 120 may control the second current control module 321 so that the second discharge current rises as much as the first discharge current is lowered. For example, when the first discharge current is adjusted to be lowered from about 250 mA to about 200 mA in operation 505, in operation 507, the processor 120 may adjust the second discharge current of the second battery 322 to rise from about 250 mA to about 300 mA, through the second current control module 321. According to an embodiment, the processor 120 may preconfigure a supportable current amount (e.g., about 300 mA) of the second battery 322, and adjust the second discharge current of the second battery 322, based on the supportable current amount. For example, a supportable current amount of the second battery 322 may be a maximum or large amount of current which can be supplied from the second battery 322 to the electronic device 101.

According to an embodiment, when the temperature of the first battery 312 and the temperature of the second battery 322 correspond to the first reference value in operation 503, the processor 120 may determine the first discharge current and the second discharge current so that a total amount of current supplied to the system is maintained substantially the same as that in the basic state (e.g., a total current amount of about 500 mA (e.g., a first discharge current amount of about 250 mA+a second discharge current amount of about 250 mA). For example, in operation 505, the processor 120 may determine the first discharge current of the first battery 312 to be about 200 mA, and in operation 507, the processor 120 may determine the second discharge current of the second battery 322 to be about 300 mA. The processor 120 may adjust the first discharge current and the second discharge current so that the total amount of current supplied to the system is maintained.

In operation 509, the processor 120 may measure a temperature of each of the first battery 312 and the second battery 322, and identify whether the temperature of the first battery 312 and the temperature of the second battery 322 correspond to the second reference value. Referring to (Table 1), when a difference value between a first temperature value of the first battery 312 and a second temperature value of the second battery 322 is included within the range of about 6-10 degrees, the processor 120 may determine that the temperatures correspond to the second reference value. For another example, when at least one of the first temperature value of the first battery 312 and the second temperature value of the second battery 322 is included within the range of about 40-42 degrees (e.g., an absolute temperature), the processor 120 may determine that the temperatures correspond to the second reference value. A condition corresponding to the second reference value may include a (2-1)th condition in which the difference between the first temperature value and the second temperature value is included within the range of about 6-10 degrees, and a (2-2)th condition in which at least one of the first temperature value and the second temperature value is included within the range of about 40-42 degrees. The processor 120 may determine that the temperatures correspond to the second reference value when at least one of the (2-1)th condition and the (2-2)th condition is satisfied.

When the temperature of the first battery 312 and the temperature of the second battery 322 correspond to the second reference value in operation 509, in operation 511, the processor 120 may perform a secondary control for the first discharge current of the first battery 312 by using the first current control module 311. For example, when the temperature of the first battery 312 rises by about 6-10 degrees higher than the temperature of the second battery 322, the processor 120 may control the first current control module 311 so that the first discharge current of the first battery 312 is lowered than a current value (e.g., a current value of the “primary controlled” first discharge current) of operation 505. For example, when a current of about 200 mA is discharged from the first battery 312 at the first reference value in operation 505, in operation 509, the processor 120 may discharge a current of about 100 mA from the first battery 312, through the first current control module 311. In operation 511, the processor 120 may discharge a current of about 300 mA from the second battery 322, through the second current control module 321.

In operation 513, the processor 120 may perform a primary function control for the system (e.g., at least one component of the electronic device 101). In operation 513, when a total amount of current (e.g., the first discharge current+the second discharge current) is lowered than that in the basic state (e.g., a total current amount of about 500 mA), the processor 120 may at least partially limit, or stop functions of the system. For example, in operation 511, the processor 120 may determine the first discharge current of the first battery 312 to be about 100 mA, and maintain the second discharge current of the second battery 322 to be about 300 mA. A total amount of current supplied to the electronic device 101 may be measured as about 400 mA. According to an embodiment, since a total amount of current (e.g., about 400 mA) supplied to the system is less than a total amount of current (e.g., about 500 mA) required in the basic state, the processor 120 may perform the primary function control for the system. For example, the primary function control may include an operation of limiting or stopping at least some of functions of the system.

In operation 515, the processor 120 may measure a temperature of each of the first battery 312 and the second battery 322, and identify whether the temperature of the first battery 312 and the temperature of the second battery 322 correspond to the third reference value. Referring to (Table 1), when a difference value between a first temperature value of the first battery 312 and a second temperature value of the second battery 322 exceeds about 10 degrees, the processor 120 may determine that the temperatures correspond to the third reference value. For another example, when at least one of the first temperature value of the first battery 312 and the second temperature value of the second battery 322 exceeds about 42 degrees (e.g., an absolute temperature), the processor 120 may determine that the temperatures correspond to the third reference value. A condition corresponding to the third reference value may include a (3-1)th condition in which the difference between the first temperature value and the second temperature value exceeds about 10 degrees, and a (3-2)th condition in which at least one of the first temperature value and the second temperature value exceeds about 42 degrees. The processor 120 may determine that the temperatures correspond to the third reference value when at least one of the (3-1)th condition and the (3-2)th condition is satisfied.

When the temperature of the first battery 312 and the temperature of the second battery 322 correspond to the third reference value in operation 515, in operation 517, the processor 120 may perform a tertiary control for the first discharge current of the first battery 312 by using the first current control module 311. For example, when the temperature of the first battery 312 rises by more than about 10 degrees above the temperature of the second battery 322, the processor 120 may control the first current control module 311 so that the first discharge current of the first battery 312 is lowered than a current value (e.g., a current value of the “secondary controlled” first discharge current) of operation 511. For example, when a current of about 100 mA is discharged from the first battery 312 at the second reference value in operation 511, in operation 517, the processor 120 may discharge a current of about 0 mA from the first battery 312 through the first current control module 311. In operation 517, the processor 120 may discharge a current of about 300 mA from the second battery 322 through the second current control module 321.

In operation 519, the processor 120 may perform a secondary function control for the system (e.g., at least one component of the electronic device 101). In operation 519, when a total amount of current (e.g., the first discharge current+the second discharge current) is lowered than that in the primary function control state (e.g., a total current amount of about 400 mA) of operation 513, the processor 120 may at least partially limit, or stop the functions of the system. For example, in operation 517, the processor 120 may determine the first discharge current of the first battery 312 to be about 0 mA, and maintain the second discharge current of the second battery 322 to be about 300 mA. A total amount of current supplied to the electronic device 101 may be measured as about 300 mA. According to an embodiment, since a total amount of current (e.g., about 300 mA) supplied to the system is less than a total amount of current (e.g., about 500 mA) required in the basic state, the processor 120 may perform the secondary function control for the system. For example, the secondary function control may include an operation of limiting or stopping at least some of functions of the system relatively more strongly than the primary function control. According to an embodiment, when the secondary function control for the system is performed, the processor 120 may cut off a discharge current supplied from the first battery 312 and supply the discharge current to the system by using only the second battery 322.

A situation in which the electronic device 101 operates in the flowchart of FIG. 5 may be shown in (Table 2) and (Table 3) below.

TABLE 2

| | | Discharge | Discharge | |
|---|---|---|---|---|
| | Temperature | current of | current of | Control of |
| Steps | difference | first battery | second battery | system |
| Basic state | About 3 | Default | Default | Normal |
| | degrees | current | current | operation |
| | or less | (about 250 | (about 250 | |
| | | mA) | mA) | |
| First | Range of | Primary | Supportable | Normal |
| reference | about 3-6 | discharge | current | operation |
| value | degrees | current | (about 300 | |
| | | (about 200 | mA) | |
| | | mA) | | |
| Second | Range of | Secondary | Supportable | Primary |
| reference | about 6-10 | discharge | current | function |
| value | degrees | current | (About 300 | control |
| | | (about 100 | mA) | |
| | | mA) | | |
| Third | About 10 | Tertiary | Supportable | Secondary |
| reference | degrees or | discharge | current | function |
| value | more | current | (About 300 | control |
| | | (about 0 mA) | mA) | |

(Table 2) shows a situation in which control steps are sequentially changed based on the temperature difference between the first battery 312 and the second battery 322.

TABLE 3

| | Measured | | | |
|---|---|---|---|---|
| | temperature | Discharge | Discharge | |
| | (e.g., absolute | current of | current of | Control of |
| Steps | temperature) | first battery | second battery | system |
| Basic state | About 38 | Default | Default | Normal |
| | degrees or | current | current | operation |
| | less | (about 250 | (about 250 | |
| | | mA) | mA) | |
| First | Range of | Primary | Supportable | Normal |
| reference | about 38-40 | discharge | current | operation |
| value | degrees | current | (about 300 | |
| | | (about 200 | mA) | |
| | | mA) | | |
| Second | Range of | Secondary | Supportable | Primary |
| reference | about 40-42 | discharge | current | function |
| value | degrees | current | (about 300 | control |
| | | (about 100 | mA) | |
| | | mA) | | |
| Third | About 42 | Tertiary | Supportable | Secondary |
| reference | degrees or | discharge | current | function |
| value | more | current | (about 300 | control |
| | | (about 0 mA) | mA) | |

(Table 3) shows a situation in which control steps are sequentially changed based on measured temperatures (e.g., absolute temperatures) of the first battery 312 and the second battery 322.

According to an embodiment, the electronic device 101 may operate with the primary function control and the secondary function control, based on a total amount of current, and may at least partially limit functions of at least one component. (Table 4) shows a situation in which functions of at least one component are limited.

TABLE 4

| | | | | | | Total |
|---|---|---|---|---|---|---|
| | | | | | | current |
| | Maximum | Camera | Camera | | | amount |
| Function | brightness | oper- | frame | Volume | Lens | of |
| control | of screen | ation | rate | size | control | system |
| Basic | About | Oper- | 90 fps | About | About | About |
| state | 100% | ation | | 100% | 100% | 500 mA |
| Primary | About | Oper- | 60 fps | About | About | About |
| control | 70% | ation | | 70% | 70% | 400 mA |
| Secondary | About | Not | 30 fps | About | About | About |
| control | 50% | oper- | | 50% | 50% | 300 mA |
| | | ation | | | | |
| Tertiary | About | Not | Not | About | About | About |
| control | 30% | oper- | oper- | 30% | 30% | 100 mA |
| | | ation | ation | | | |

(Table 4) shows a situation in which functions of at least one component are sequentially controlled based on a total amount of current supplied to the system of the electronic device 101.

According to another embodiment, the electronic device 101 may identify a residual capacity of a battery and at least partially control the system, based on the identified residual capacity of the battery. According to an embodiment, the first current control module 311 and the second current control module 321 may include a fuel gauge module for measuring a residual capacity of the battery. For example, a current control module and the fuel gauge module may be designed to be integrated into one module. The first current control module 311 may include a first fuel gauge module, and the processor 120 may measure a residual capacity of the first battery 312 by using the first fuel gauge module. The second current control module 321 may include a second fuel gauge module, and the processor 120 may measure a residual capacity of the second battery 322 by using the second fuel gauge module.

According to another embodiment, in the electronic device 101, due to a malfunction of the first battery 312 (e.g., temperature rise of the first battery 312), the system may be driven based on the second discharge current of the second battery 322, and the speed at which the second battery 322 is discharged may be increased. According to another embodiment, the electronic device 101 may identify a residual capacity of the second battery 322 in order to increase an operating time of the system, and perform an additional function control for the system, based on the identified residual capacity. (Table 5) shows a situation in which the second discharge current of the second battery 322 is controlled according to a change in the residual capacity of the second battery 322.

TABLE 5

| Residual capacity information | Second discharge current of second |
|---|---|
| of second battery | battery |
| About 30% or more | Supportable current (about 300 mA) |
| Range of about 15-30% | Primary discharge current (about 200 mA) |
| About 15% or less | Secondary discharge current (about 100 |
| | mA) |

Referring to (Table 5), the processor 120 may determine the second discharge current of the second battery 322, through the second current control module 321, based on the residual capacity information of the second battery 322. For example, when the residual capacity of the second battery 322 is about 30% or more, the processor 120 may maintain the second discharge current of the second battery 322 at a supportable current amount (e.g., about 300 mA). For example, the supportable current amount may be a maximum or high amount of current configured with respect to the second battery 322. When the residual capacity of the second battery 322 is included within the range of about 15-30%, the processor 120 may lower the second discharge current of the second battery 322 to a primary discharge current (e.g., about 200 mA). According to another embodiment, the electronic device 101 may measure residual capacity information of a battery by using a fuel gauge module, and determine a discharge current of the battery, based on the measured residual capacity information of the battery.

(Table 6) shows a situation in which the first battery 312, the second battery 322, and the system are controlled by integrating control steps for the electronic device 101 and residual capacity information of the second battery 322.

TABLE 6

| | Discharge current | Discharge current | Control of |
|---|---|---|---|
| Steps | of first battery | of second battery | system |
| Basic state + about | Default current | Default current | Normal |
| 30% or more of | (about 250 mA) | (about 250 mA) | operation |
| residual capacity | | | |
| of second battery | | | |
| First reference | Primary discharge | Supportable | Normal |
| value + about 30% | current | current | operation |
| or more of residual | (about 200 mA) | (about 300 mA) | |
| capacity of second | | | |
| battery | | | |
| Second reference | Secondary | Primary discharge | Primary |
| value + range of | discharge current | current | function |
| about 15-30% of | (about 100 mA) | (about 200 mA) | control |
| residual capacity | | | |
| of second battery | | | |
| Third reference | Tertiary discharge | Secondary | Secondary |
| value + about 15% | current | discharge current | function |
| or less of residual | (about 0 mA) | (about 100 mA) | control |
| capacity of second | | | |
| battery | | | |

(Table 6) shows a situation in which the second discharge current of the second battery 322 is determined by integrating control steps for the electronic device 101 and residual capacity information of the second battery 322.

According to an embodiment, the processor 120 may store a plurality of reference values (e.g., a first reference value, a second reference value, and/or a third reference value) configured based on a temperature of the first battery 312 and a temperature of the second battery 322 in a memory (e.g., the memory 130 of FIG. 1). The processor 120 may measure the temperature of the first battery 312 and the temperature of the second battery 322 to determine the first discharge current of the first battery 312 and the second discharge current of the second battery 322 in stages and sequentially. According to an embodiment, the processor 120 may include a current control module (e.g., the first current control module 311 of FIG. 3 and/or the second current control module 321 of FIG. 3) corresponding to each battery, and independently determine a discharge current of a battery through each current control module. According to an embodiment, the processor 120 may determine a total amount of current supplied to the system, based on the first discharge current and the second discharge current, and at least partially limit, or stop functions of at least one component configuring the system, based on the determined total amount of current.

According to an embodiment, in the electronic device 101 including the first battery 312 and the second battery 322, in response to a situation in which the first battery 312 malfunctions (e.g., a situation in which the temperature of the first battery 312 rises), the processor 120 may determine to raise the second discharge current of the second battery 322 while determining to reduce the first discharge current of the first battery 312. According to an embodiment, the processor 120 may at least partially limit the functions of the system when a total amount of current in which the first discharge current and the second discharge current are integrated is lower than a total amount of current required in the system in the basic state.

According to another embodiment, the electronic device 101 may identify residual capacity information of a battery and additionally further limit the functions of the system, based on the residual capacity information of the battery.

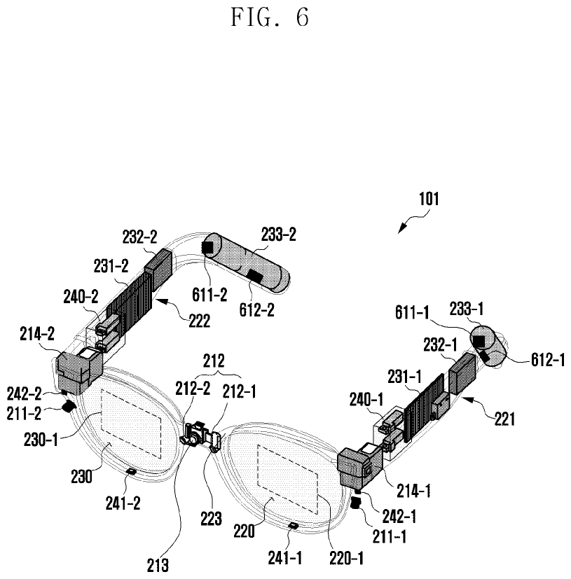

FIG. 6 is a configuration diagram of an electronic device in which a plurality of batteries and a temperature sensor for measuring a temperature of each of the batteries are disposed, according to various example embodiments.

An electronic device (e.g., the electronic device 101 of FIG. 1) of FIG. 6 may be at least partially similar to the electronic device 101 (e.g., an AR device or a wearable electronic device) of FIG. 2, or may further include other embodiments of the electronic device 101.

According to an embodiment, the electronic device 101 may include an augmented reality (AR) electronic device which is worn on a user's head part and provides an augmented reality service. For example, the electronic device 101 may be configured in the form of at least one of glasses, goggles, a helmet, or a hat, but is not limited thereto.

Referring to FIG. 6, the electronic device 101 may include the first support portion 221 and the second support portion 222 to be at least partially mounted on a user's ear part. In the first support part 221, the first battery 233-1 may be disposed on a left auricle part of the user, and may maintain a state of being at least partially in close contact with the human body. In the second support part 222, the second battery 233-2 may be disposed on a right auricle part of the user, and may maintain a state of being at least partially in close contact with the human body.

According to an embodiment, the electronic device 101 may include first temperature sensors 611-1 and 612-1 for measuring a temperature of the first battery 233-1 in the first support portion 221, and include second temperature sensors 611-2 and 612-2 for measuring a temperature of the second battery 233-2 in the second support portion 222. For example, the first temperature sensors 611-1 and 612-1 may be disposed at least partially in close contact with the first battery 233-1 in order for accurate temperature measurement, and directly measure the temperature of the first battery 233-1. For another example, the first temperature sensors 611-1 and 612-1 may be disposed between the first battery 233-1 and the human body to measure a relative temperature change amount with reference to the body temperature (e.g., about 36.5 degrees).

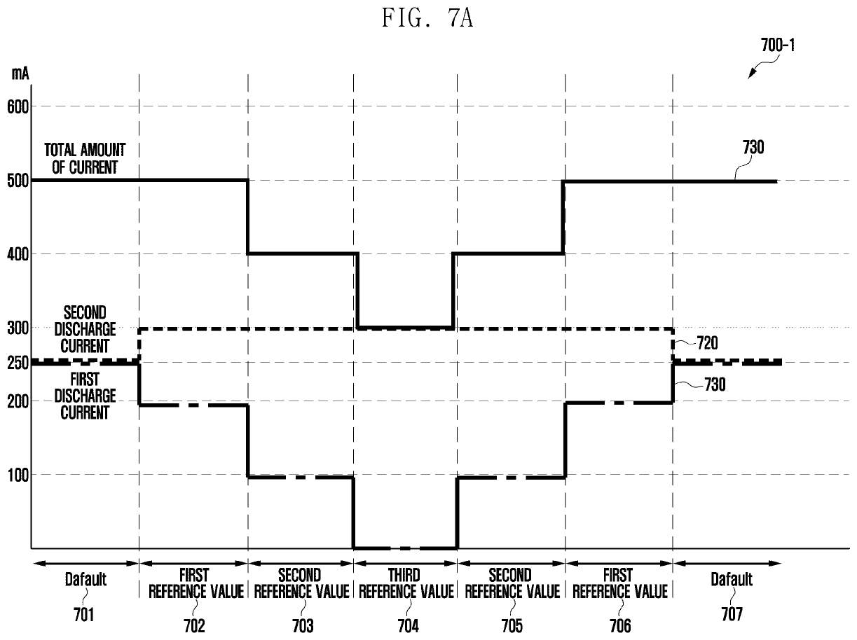

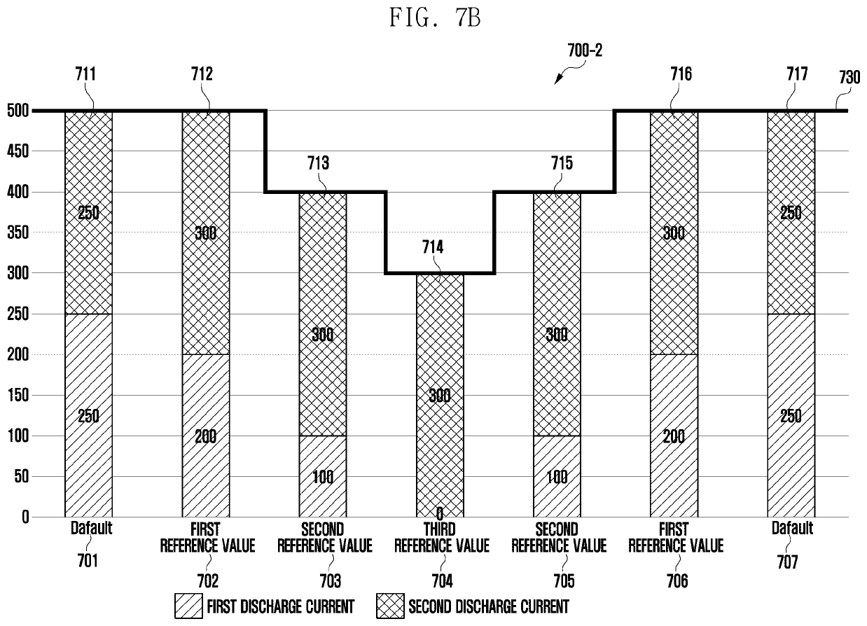

FIG. 7A is a first graph 700-1 illustrating a situation in which a first current discharged from a first battery is reduced while a second current discharged from a second battery is maintained at a supportable level, according to various example embodiments. FIG. 7B is a second graph 700-2 illustrating a total amount of current supplied to an electronic device in a situation in which a first discharge current of a first battery is reduced while a second discharge current of a second battery is maintained at a supportable level, according to various example embodiments.

An electronic device (e.g., the electronic device 101 of FIG. 1) disclosed in FIGS. 7A and 7B may be at least partially similar to the electronic device 101 (e.g., an AR device or a wearable electronic device) of FIG. 2, or may further include other embodiments of the electronic device 101.

According to an embodiment, the electronic device 101 may include an AR electronic device including a first battery (e.g., the first battery 312 of FIG. 3) and a second battery (e.g., the second battery 322 of FIG. 3). The first graph 700-1 of FIG. 7A may include a first discharge current graph 710 illustrating a first discharge current amount discharged from the first battery 312, a second discharge current graph 720 illustrating a second discharge current amount discharged from the second battery 322, and/or a total current amount graph 730 in which the first discharge current amount and the second discharge current amount are integrated. The second graph 700-2 of FIG. 7B illustrates a graph comparing the first discharge current amount and the second discharge current amount, based on the total current amount graph 730.

Referring to FIG. 7A, in a base state 701 (e.g., default) (e.g., a state in which the electronic device 101 normally operates), a processor (e.g., the processor 120 of FIG. 1) may determine the first discharge current amount of the first battery 312 to be about 250 mA and the second discharge current amount of the second battery 322 to be about 250 mA, and a total amount of current supplied to a system may be about 500 mA. (e.g., 711 of FIG. 7B)

The processor 120 may determine the first discharge current amount to be about 200 mA and determine the second discharge current amount to be about 300 mA, in response to a situation 702 in which a first reference value is satisfied. For example, when the temperature of the first battery 312 rises and thus the first reference value is satisfied (e.g., a condition in which the difference between the temperature of the first battery 312 and the temperature of the second battery 322 is included within the range of about 3-6 degrees), the processor 120 may determine to increase a second discharge current value of the second battery 322 while determining to reduce a first discharge current value of the first battery 312. For example, the second discharge current value may be determined to be a current value supportable by the second battery 322. According to an embodiment, the processor 120 may determine the increase width of the second discharge current value as much as the decrease width of the first discharge current so as to maintain a total amount of current (e.g., about 500 mA) in the basic state. In the situation 702 in which the first reference value is satisfied, the processor 120 may maintain the total amount of current supplied to the system at about 500 mA. (e.g., 712 of FIG. 7B)

The processor 120 may determine the first discharge current amount to be about 100 mA and determine the second discharge current amount to be about 300 mA, in response to a situation 703 in which a second reference value is satisfied. For example, when the temperature of the first battery 312 rises more and thus the second reference value is satisfied (e.g., a condition in which the difference between the temperature of the first battery 312 and the temperature of the second battery 322 is included within the range of about 6-10 degrees), the processor 120 may maintain the second discharge current value (e.g., a current value supportable by the second battery 322) of the second battery 322 while determining to further reduce the first discharge current value of the first battery 312. According to an embodiment, the processor 120 may determine the total amount of current supplied to the system to be about 400 mA in the situation 703 in which the second reference value is satisfied. (e.g., 713 of FIG. 7B) According to an embodiment, as the total amount of current supplied to the system decreases, the processor 120 may at least partially limit functions of at least one component configuring the system.

The processor 120 may determine the first discharge current amount to be about 0 mA and determine the second discharge current amount to be about 300 mA, in response to a situation 704 in which a third reference value is satisfied. For example, when the temperature of the first battery 312 rises much more and thus the third reference value is satisfied (e.g., a condition in which the difference between the temperature of the first battery 312 and the temperature of the second battery 322 exceeds about 10 degrees), the processor 120 may maintain the second discharge current value (e.g., a current value supportable by the second battery 322) of the second battery 322 while blocking a first discharge current of the first battery 312. According to an embodiment, the processor 120 may determine the total amount of current supplied to the system to be about 300 mA in the situation 704 in which the third reference value is satisfied. (e.g., 714 of FIG. 7B) According to an embodiment, as the total amount of current supplied to the system decreases, the processor 120 may at least partially limit, or stop functions of at least one component configuring the system.

In response to a change from the situation 704 in which the third reference value is satisfied to a situation 705 in which the temperature of the first battery 312 is lowered and thus the second reference value is satisfied, the processor 120 may determine the first discharge current amount to be about 100 mA and determine the second discharge current amount to be about 300 mA. For example, when the temperature of the first battery 312 is lowered than before and thus the second reference value is satisfied (e.g., a condition in which the difference between the temperature of the first battery 312 and the temperature of the second battery 322 is included within the range of about 6-10 degrees), the processor 120 may maintain the second discharge current value (e.g., a current value supportable by the second battery 322) of the second battery 322 while determining to raise the first discharge current value of the first battery 312 to be higher than before. According to an embodiment, the processor 120 may determine the total amount of current supplied to the system to be about 400 mA when the situation in which the third reference value is satisfied is changed to the situation in which the second reference value is satisfied 705. (e.g., 715 of FIG. 7B) According to an embodiment, as the total amount of current supplied to the system increases more than before, the processor 120 may additionally perform functions of at least one component configuring the system.

In response to a change from the situation 705 in which the second reference value is satisfied to a situation 706 in which the temperature of the first battery 312 is lowered and thus the first reference value is satisfied, the processor 120 may determine the first discharge current amount to be about 200 mA and determine the second discharge current amount to be about 300 mA. For example, when the temperature of the first battery 312 is lowered than before and thus the first reference value is satisfied (e.g., a condition in which the difference between the temperature of the first battery 312 and the temperature of the second battery 322 is included within the range of about 3-6 degrees), the processor 120 may maintain the second discharge current value (e.g., a current value supportable by the second battery 322) of the second battery 322 while determining to raise the first discharge current value of the first battery 312 to be higher than before. According to an embodiment, the processor 120 may determine the total amount of current supplied to the system to be about 500 mA when the situation in which the second reference value is satisfied is changed to the situation in which the first reference value is satisfied 706. (e.g., 716 of FIG. 7B) According to an embodiment, as the total amount of current supplied to the system is determined to be about 500 mA which is the same as the basic state 701 and the first reference value 702, the processor 120 may perform a normal operation for the system.

In response to a change from the situation 706 in which the first reference value is satisfied to a basic state 707 due to lowering of the temperature of the first battery 312, the processor 120 may determine the first discharge current amount to be about 250 mA and determine the second discharge current amount to be about 250 mA. For example, when the temperature of the first battery 312 is lowered more than before and thus the first reference value is satisfied (e.g., a condition in which the difference between the temperature of the first battery 312 and the temperature of the second battery 322 is about 3 degrees or less), the processor 120 may determine to reduce the second discharge current value of the second battery 322 to be lower than before while determining to raise the first discharge current value of the first battery 312 to be higher than before. For example, in the basic state, the first discharge current value and the second discharge current value may be determined to be substantially the same current value. According to an embodiment, the processor 120 may determine the total amount of current supplied to the system to be about 500 mA when the situation in which the first reference value is satisfied is changed to the basic state 707. (e.g., 717 of FIG. 7B) According to an embodiment, as the total amount of current supplied to the system is determined to be about 500 mA which is the same as the basic state 701, the processor 120 may perform a normal operation for the system.

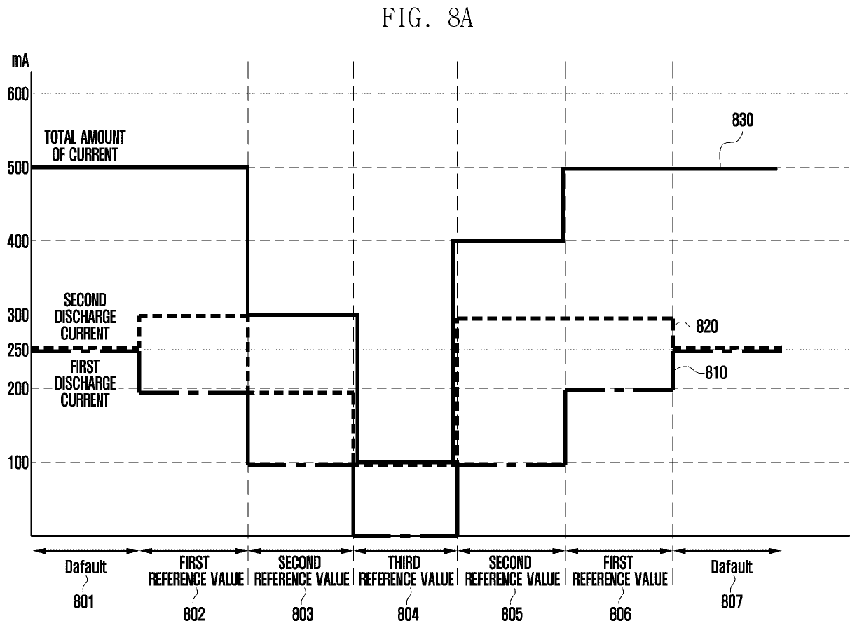

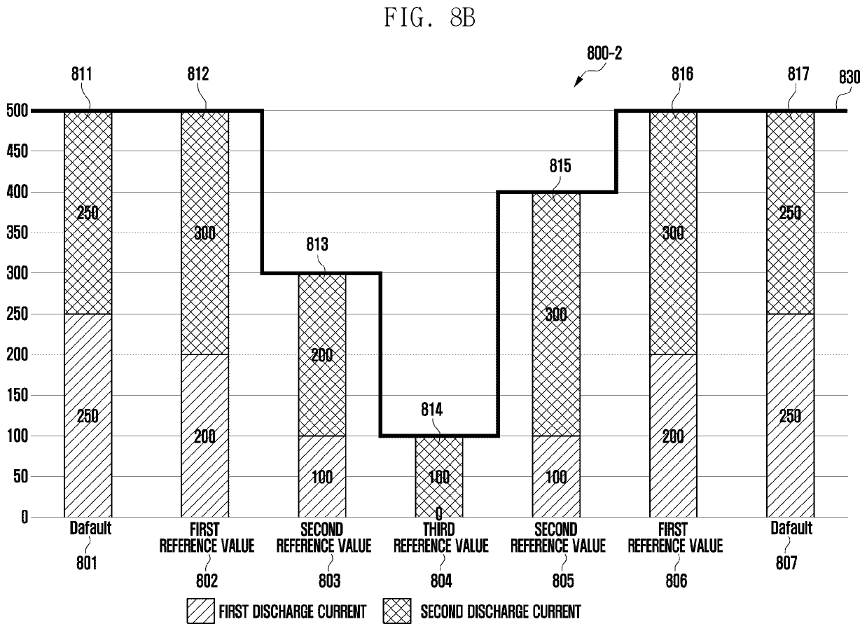

FIG. 8A is a third graph 800-1 illustrating a situation in which a first discharge current of a first battery and a second discharge current of a second battery are reduced, according to various example embodiments. FIG. 8B is a fourth graph 800-2 illustrating a total amount of current supplied to an electronic device in a situation in which a first discharge current of a first battery and a second discharge current of a second battery are reduced, according to various example embodiments.

An electronic device (e.g., the electronic device 101 of FIG. 1) disclosed in FIGS. 8A and 8B may be at least partially similar to the electronic device 101 (e.g., an AR device or a wearable electronic device) of FIG. 2, or may further include other embodiments of the electronic device 101. FIGS. 8A and 8B illustrate an embodiment different from the embodiment shown in FIGS. 7A and 7B.

According to an embodiment, the electronic device 101 may include an AR electronic device including a first battery (e.g., the first battery 312 of FIG. 3) and a second battery (e.g., the second battery 322 of FIG. 3). The first graph 800-1 of FIG. 8A may include a first discharge current graph 810 illustrating a first discharge current amount discharged from the first battery 312, a second discharge current graph 820 illustrating a second discharge current amount discharged from the second battery 322, and/or a total current amount graph 830 in which the first discharge current amount and the second discharge current amount are integrated. The second graph 800-2 of FIG. 8B illustrates a graph comparing the first discharge current amount and the second discharge current amount, based on the total current amount graph 830.

A basic state 801 and a situation 802 in which a first reference value is satisfied of FIG. 8A are the same as the basic state 701 and the situation 702 in which the first reference value is satisfied of FIG. 7A, and the description thereof is replaced with the detailed description of FIG. 7A.

In response to a change from the situation 802 in which the first reference value is satisfied to a situation 803 in which a second reference value is satisfied, the processor 120 of the electronic device 101 may determine the first discharge current amount to be about 100 mA and determine the second discharge current amount to be about 200 mA. For example, when the temperature of the first battery 312 rises more and thus the second reference value is satisfied (e.g., a condition in which the difference between the temperature of the first battery 312 and the temperature of the second battery 322 is included within the range of about 6-10 degrees), the processor 120 may also determine to reduce a second discharge current value of the second battery 322 while determining to further reduce a first discharge current value of the first battery 312. According to an embodiment, the processor 120 may determine a total amount of current supplied to a system to be about 300 mA in the situation 803 in which the second reference value is satisfied. (e.g., 813 of FIG. 8B) According to an embodiment, as the total amount of current supplied to the system decreases, the processor 120 may at least partially limit functions of at least one component configuring the system.

In response to a change from the situation 803 in which the second reference value is satisfied to a situation 804 in which a third reference value is satisfied, the processor 120 may determine the first discharge current amount to be about 0 mA and determine the second discharge current amount to be about 100 mA. For example, when the temperature of the first battery 312 rises much more and thus the third reference value is satisfied (e.g., a condition in which the difference between the temperature of the first battery 312 and the temperature of the second battery 322 exceeds about 10 degrees), the processor 120 may determine to further reduce the second discharge current value of the second battery 322 while blocking a first discharge current of the first battery 312. According to an embodiment, the processor 120 may determine the total amount of current supplied to the system to be about 200 mA in the situation 804 in which the third reference value is satisfied. (e.g., 814 of FIG. 8B) According to an embodiment, as the total amount of current supplied to the system decreases, the processor 120 may at least partially limit, or stop functions of at least one component configuring the system.

In response to a change from the situation 804 in which the third reference value is satisfied to a situation 805 in which the temperature of the first battery 312 is lowered and thus the second reference value is satisfied, the processor 120 may determine the first discharge current amount to be about 100 mA and determine the second discharge current amount to be about 300 mA. For example, when the temperature of the first battery 312 is lowered than before and thus the second reference value is satisfied (e.g., a condition in which the difference between the temperature of the first battery 312 and the temperature of the second battery 322 is included within the range of about 6-10 degrees), the processor 120 may determine to raise the second discharge current value (e.g., a maximum or high discharge current value) of the second battery 322 by an amount larger than the amount of rising of the first discharge current value while determining to raise the first discharge current value of the first battery 312 to be higher than before. According to an embodiment, the processor 120 may determine the total amount of current supplied to the system to be about 400 mA when the situation in which the third reference value is satisfied is changed to the situation in which the second reference value is satisfied 805. (e.g., 815 of FIG. 8B) According to an embodiment, as the total amount of current supplied to the system increases more than before, the processor 120 may additionally perform functions of at least one component configuring the system.

In response to a change from the situation 805 in which the second reference value is satisfied to a situation 806 in which the temperature of the first battery 312 is lowered and thus the first reference value is satisfied, the processor 120 may determine the first discharge current amount to be about 200 mA and determine the second discharge current amount to be about 300 mA. For example, when the temperature of the first battery 312 is lowered than before and thus the first reference value is satisfied (e.g., a condition in which the difference between the temperature of the first battery 312 and the temperature of the second battery 322 is included within the range of about 3-6 degrees), the processor 120 may maintain the second discharge current value (e.g., a supportable current value) of the second battery 322 while determining to raise the first discharge current value of the first battery 312 to be higher than before. According to an embodiment, the processor 120 may determine the total amount of current supplied to the system to be about 500 mA when the situation in which the second reference value is satisfied is changed to the situation in which the first reference value is satisfied 806. (e.g., 816 of FIG. 8B) According to an embodiment, as the total amount of current supplied to the system is determined to be about 500 mA which is the same as the basic state 801 and the first reference value 802, the processor 120 may perform a normal operation for the system.

In response to a change to from the situation 806 in which the first reference value is satisfied a basic state 807 due to lowering of the temperature of the first battery 312, the processor 120 may determine the first discharge current amount to be about 250 mA and determine the second discharge current amount to be about 250 mA. For example, when the temperature of the first battery 312 is lowered more than before and thus the first reference value is satisfied (e.g., a condition in which the difference between the temperature of the first battery 312 and the temperature of the second battery 322 is about 3 degrees or less), the processor 120 may determine to reduce the second discharge current value of the second battery 322 to be lower than before while determining to raise the first discharge current value of the first battery 312 to be higher than before. For example, in the basic state, the first discharge current value and the second discharge current value may be determined to be substantially the same current value. According to an embodiment, the processor 120 may determine the total amount of current supplied to the system to be about 500 mA when the situation in which the first reference value is satisfied is changed to the basic state 807. (e.g., 817 of FIG. 8B) According to an embodiment, as the total amount of current supplied to the system is determined to be about 500 mA which is the same as the basic state 801, the processor 120 may perform a normal operation for the system.

A method according to various embodiments may include measuring a temperature of a first battery (e.g., the first battery 312 of FIG. 3) and a temperature of a second battery (e.g., the second battery 322 of FIG. 3) by using a sensor module (e.g., the sensor module 176 of FIG. 1), identifying whether at least one reference condition is satisfied, based on the measured temperature of the first battery 312 and the measured temperature of the second battery 322, controlling a first discharge current of the first battery 312 by using a first current control module (e.g., the first current control module 311 of FIG. 3) when the at least one reference condition is satisfied, and controlling a second discharge current of the second battery 322 by using a second current control module (e.g., the second current control module 321 of FIG. 3) when the at least one reference condition is satisfied.

According to an embodiment, the identifying of whether the at least one reference condition is satisfied may include calculating a difference value between the temperature of the first battery 312 and the temperature of the second battery 322 to identify whether the difference value exceeds a configured reference value, identifying whether at least one of the temperature of the first battery and the temperature of the second battery exceeds a configured absolute reference value, and identifying that the at least one reference condition is satisfied, when the difference value exceeds the reference value or at least one of the temperature of the first battery and the temperature of the second battery exceeds the absolute reference value.

The method according to an embodiment may further include identifying a battery of which the temperature has risen relatively higher among the first battery 312 and the second battery 322 when it is identified that the at least one reference condition is satisfied, and configuring a discharge current of the identified battery to be low, by using a current control module corresponding to the identified battery.

The method according to an embodiment may further include configuring the first discharge current of the first battery 312 to be low by using the first current control module 311, when the temperature of the first battery 312 has risen higher than the temperature of the second battery 322 and thus the difference value exceeds the configured reference value, and configuring the second discharge current of the second battery 322 to be high by using the second current control module 321, when the temperature of the first battery 312 has risen higher than the temperature of the second battery 322 and thus the difference value exceeds the configured reference value.

According to an embodiment, the reference value includes a first reference value and a second reference value, the absolute reference value includes a first absolute reference value and a second absolute reference value, the second reference value is relatively greater than the first reference value, and the second absolute reference value is relatively greater than the first absolute reference value.

In the method according to an embodiment, a discharge current of the first battery 312 when the difference value exceeds the first reference value in a situation in which the temperature of the first battery 312 is relatively higher than the temperature of the second battery 322 is greater than a discharge current of the first battery 312 when the difference value exceeds the second reference value, and a discharge current determined based on the first absolute reference value is greater than a discharge current determined based on the second absolute reference value.

The method according to an embodiment may further include identifying a total amount of current supplied to a system of the electronic device 101, based on the first discharge current and the second discharge current, and at least partially limiting a function of the system, based on the identified total amount of current.

In the method according to an embodiment, the first current control module 311 may include a first battery capacity measurement module, comprising circuitry, configured to measure a residual capacity of the first battery 312, and the method may further include measuring the residual capacity of the first battery 312 by using the first battery capacity measurement module, and determining the first discharge current of the first battery 312 by using the first current control module 311, based on the measured residual capacity of the first battery 312.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd.” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via at least a third element(s).

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC). Thus, each “module” herein may comprise circuitry.

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various embodiments, it will be understood that the various embodiments are intended to be illustrative, not limiting. It will further be understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

1. An electronic device comprising:
a first battery;
a second battery connected in parallel with the first battery;
a first current control module, comprising circuitry, configured to control a first discharge current of the first battery;
a second current control module, comprising circuitry, configured to control a second discharge current of the second battery;
a sensor module, comprising at least one sensor, configured to sense a temperature of the first battery and a temperature of the second battery;
a memory; and
a processor operatively connected to the first current control module, the second current control module, the sensor module, and the memory,
wherein the processor is configured to:
measure the temperature of the first battery and the temperature of the second battery via at least the sensor module;
identify whether at least one reference condition is satisfied, based on the temperature of the first battery and the temperature of the second battery; and
based on the at least one reference condition being satisfied, control the first discharge current of the first battery via the first current control module, and control the second discharge current of the second battery via the second current control module.

2. The electronic device of claim 1, wherein the processor is configured to:
calculate a difference value between the temperature of the first battery and the temperature of the second battery, at least to identify whether the difference value exceeds a configured reference value, and/or
identify whether at least one of the temperature of the first battery and the temperature of the second battery exceeds a configured absolute reference value; and
identify that the at least one reference condition is satisfied, based on the difference value exceeding the reference value and/or at least one of the temperature of the first battery and the temperature of the second battery exceeding the absolute reference value.

3. The electronic device of claim 2, wherein the processor is configured to:
based on the at least one reference condition being identified as having been satisfied, identify a battery of which a temperature has risen relatively higher among the first battery and the second battery; and
configure a discharge current of the identified battery to be low, via a current control module, comprising circuitry, corresponding to the identified battery.

4. The electronic device of claim 3, wherein the processor is configured to:
configure the first discharge current of the first battery to be low via the first current control module, when the temperature of the first battery has risen higher than the temperature of the second battery and thus the difference value exceeds the configured reference value; and
configure the second discharge current of the second battery to be high via the second current control module, when the temperature of the first battery has risen higher than the temperature of the second battery and thus the difference value exceeds the configured reference value.

5. The electronic device of claim 4, wherein the processor is configured to configure the second discharge current of the second battery to a current value supportable by the second battery.

6. The electronic device of claim 2, wherein the reference value comprises a first reference value and a second reference value,
wherein the absolute reference value comprises a first absolute reference value and a second absolute reference value, and
wherein the second reference value is relatively greater than the first reference value, and the second absolute reference value is relatively greater than the first absolute reference value.

7. The electronic device of claim 6, wherein a discharge current of the first battery when the difference value exceeds the first reference value in a situation in which the temperature of the first battery is relatively higher than the temperature of the second battery, is greater than a discharge current of the first battery when the difference value exceeds the second reference value.

8. The electronic device of claim 6, wherein a discharge current determined based on the first absolute reference value is greater than a discharge current determined based on the second absolute reference value.

9. The electronic device of claim 1, wherein the processor is configured to:
identify a total amount of current supplied to a system of the electronic device, based on the first discharge current and the second discharge current; and
at least partially limit a function of the system, based on the identified total amount of current.

10. The electronic device of claim 1, wherein the sensor module comprises a first temperature sensor configured to sense a temperature of the first battery and a second temperature sensor configured to sense a temperature of the second battery, and
wherein the processor is configured to:
measure the temperature of the first battery via the first temperature sensor; and
individually measure the temperature of the second battery via the second temperature sensor.

11. The electronic device of claim 1, wherein the first current control module comprises a first battery capacity measurement module, comprising circuitry, configured to measure a residual capacity of the first battery, and
wherein the second current control module comprises a second battery capacity measurement module, comprising circuitry, configured to measure a residual capacity of the second battery.

12. The electronic device of claim 11, wherein the processor is configured to:
measure the residual capacity of the first battery via the first battery capacity measurement module;
determine the first discharge current of the first battery via the first current control module, based on the measured residual capacity of the first battery;
measure the residual capacity of the second battery via the second battery capacity measurement module; and
determine the second discharge current of the second battery via the second current control module, based on the measured residual capacity of the second battery.

13. A method comprising:
measuring a temperature of a first battery and a temperature of a second battery;
identifying whether at least one reference condition is satisfied, based on the measured temperature of the first battery and the measured temperature of the second battery;
controlling a first discharge current of the first battery, when the at least one reference condition is satisfied; and
controlling a second discharge current of the second battery, when the at least one reference condition is satisfied.

14. The method of claim 13, wherein the identifying of whether the at least one reference condition is satisfied comprises:
calculating a difference value between the temperature of the first battery and the temperature of the second battery to identify whether the difference value exceeds a configured reference value;
identifying whether at least one of the temperature of the first battery and the temperature of the second battery exceeds a configured absolute reference value; and
identifying that the at least one reference condition is satisfied, in case that the difference value exceeds the reference value or at least one of the temperature of the first battery and the temperature of the second battery exceeds the absolute reference value.

15. The method of claim 14, further comprising:
in case that the at least one reference condition is identified as having been satisfied, identifying a battery of which a temperature has risen relatively higher among the first battery and the second battery; and
configuring a discharge current of the identified battery to be low.

16. The method of claim 15, further comprising:
configuring the first discharge current of the first battery to be low, in a case that the temperature of the first battery has risen higher than the temperature of the second battery and thus the difference value exceeds the configured reference value; and
configuring the second discharge current of the second battery to be high, in a case that the temperature of the first battery has risen higher than the temperature of the second battery and thus the difference value exceeds the configured reference value.

17. The method of claim 14, wherein the reference value comprises a first reference value and a second reference value, and the absolute reference value comprises a first absolute reference value and a second absolute reference value, and
wherein the second reference value is relatively greater than the first reference value, and the second absolute reference value is relatively greater than the first absolute reference value.

18. The method of claim 17, wherein a discharge current of the first battery in case that the difference value exceeds the first reference value in a situation in which the temperature of the first battery is relatively higher than the temperature of the second battery is greater than a discharge current of the first battery in case that the difference value exceeds the second reference value, and
wherein a discharge current determined based on the first absolute reference value is greater than a discharge current determined based on the second absolute reference value.

19. The method of claim 13, further comprising:
identifying a total amount of current supplied to a system of an electronic device, based on the first discharge current and the second discharge current; and
at least partially limiting a function of the system, based on the identified total amount of current.

20. The method of claim 13,
wherein the method further comprises:
measuring the residual capacity of the first battery by using a first battery capacity measurement module comprising circuitry; and
determining the first discharge current of the first battery by using the first current control module, based on a measured residual capacity of the first battery.
